(19) United States
(12) Patent Application Publication
(10) Pub. No.: US 2024/0273261 A1
(43) Pub. Date: Aug. 15, 2024

(54) EQUIVARIANT TRAJECTORY OPTIMIZATION WITH DIFFUSION MODELS

(71) Applicant: QUALCOMM Incorporated, San Diego, CA (US)

(72) Inventors: Johann Hinrich BREHMER, Amsterdam (NL); Avishek BOSE, Montreal (CA); Pim DE HAAN, Amsterdam (NL); Taco Sebastiaan COHEN, Amsterdam (NL)

(21) Appl. No.: 18/360,502

(22) Filed: Jul. 27, 2023

Related U.S. Application Data
(60) Provisional application No. 63/484,704, filed on Feb. 13, 2023.

(51) Int. Cl. G06F 30/27; G06F 30/10

(52) U.S. Cl. CPC G06F 30/27; G06F 30/10

(57) ABSTRACT

Systems and techniques are described herein for modeling tasks using a geometric structure. An example method includes receiving, via a training preparation engine, a training dataset comprising state-action pairs, separating, via the training preparation engine, the state-action pairs from the training dataset into geometric data types, converting, via the training preparation engine, the geometric data types into internal representations, processing, via an equivariant denoising network, the internal representations to generate output data and transforming the output data to a data representation.

### PRIORITY CLAIM

This application claims the benefit of U.S. Provisional Application No. 63/484,704, filed Feb. 13, 2023, which is hereby incorporated by reference, in its entirety and for all purposes.

### TECHNICAL FIELD

The present disclosure generally relates to solutions for modeling and planning problems. For example, aspects of the present disclosure relate to an equivariant diffuser model that can solve modeling and planning problems by taking into account a symmetric geometric structure of any given problem, such as locomotion, navigation, and object manipulation by a system or device (e.g., a vehicle, a robotics system or device, etc.).

### BACKGROUND

Path modeling and planning can be used by a variety of systems or devices, such as vehicles, robotics systems, aerial vehicles or drones, and/or other systems or devices. For example, a vehicle or robotics system can determine a path for navigation purposes. In some cases, path planning can be performed using a learned model (e.g., a machine learning model, such as a neural network model). In some cases, the learned model can be input to a classical trajectory optimization routine.

### SUMMARY

Systems and techniques are described for providing a diffusion model that takes into account geometric structures for environments, such as for robotic applications. For example, the systems and techniques can exploit symmetries within the structures. The systems and techniques can generate diffusion models used in planning that include equivariance constraints based on an SE(3) group (Special Euclidean group with 3 elements), which leads to a group-invariant density over trajectories. Such diffusion models can result in gains in sample efficiency, training speed, and/or model generalizability, among other benefits.

Various systems (e.g., robots) operate in a structured world and often solve tasks with spatial, temporal, and permutation symmetries. Most reinforcement learning algorithms do not take such a structure into account. Despite remarkable successes in idealized settings, learning algorithms often require a large amount of training and generalize poorly. To improve sample efficiency, robustness, and generalization, various aspects provide an algorithm for model-based reinforcement learning and planning that is equivariant with respect to the product of the spatial symmetry group SE(3) (Special Euclidean group with 3 elements), the discrete time translation group Z, and the permutation group Sₙ. In some aspects, the systems and techniques can be based on a diffuser paradigm, which treats the learning of a dynamics model and a policy as a single generative modeling problem and trains a diffusion model to solve the problem of not taking geometric structure into account when generalizing. Both the dynamics model and policy are made invariant through a new SE(3)× [symbol] ×Sₙ-equivariant architecture for the denoising model. Conditioning and classifier-based guidance allow the approach to softly break equivariance for specific tasks as needed. An equivariant robot diffuser algorithm can be demonstrated on navigation and object manipulation tasks. Compared to unstructured diffuser baselines, the new model improves final task performance, is more sample efficient, and generalizes better across the symmetry group.

In some examples, a processor-implemented method of modeling tasks using a geometric structure includes: receiving, via a training preparation engine, a training dataset including state-action pairs; separating, via the training preparation engine, the state-action pairs from the training dataset into geometric data types; converting, via the training preparation engine, the geometric data types into internal representations; processing, via an equivariant denoising network, the internal representations to generate output data; and transforming the output data to a data representation.

In some examples, an apparatus for modeling tasks using symmetries in geometric structures can include at least one memory (e.g., configured in circuitry) and at least one processor coupled to at least one memory and configured to: receive, via a training preparation engine, a training dataset including state-action pairs; separate, via the training preparation engine, the state-action pairs from the training dataset into geometric data types; convert, via the training preparation engine, the geometric data types into internal representations; process, via an equivariant denoising network, the internal representations to generate output data; and transform the output data to a data representation.

In some examples, a non-transitory computer-readable medium is provided that has stored thereon instructions that, when executed by one or more processors, cause the one or more processors to: receive, via a training preparation engine, a training dataset including state-action pairs; separate, via the training preparation engine, the state-action pairs from the training dataset into geometric data types; convert, via the training preparation engine, the geometric data types into internal representations; process, via an equivariant denoising network, the internal representations to generate output data; and transform the output data to a data representation.

In some examples, an apparatus for performing object detection is provided. The apparatus includes: means for receiving, via a training preparation engine, a training dataset including state-action pairs; means for separating, via the training preparation engine, the state-action pairs from the training dataset into geometric data types; means for converting, via the training preparation engine, the geometric data types into internal representations; means for processing, via an equivariant denoising network, the internal representations to generate output data; and means for transforming the output data to a data representation.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and aspects, will become more apparent upon referring to the following specification, claims, and accompanying drawings.

### BRIEF DESCRIPTION OF THE DRAWINGS

Illustrative examples of the present application are described in detail below with reference to the following figures:

FIG. 1 is a diagram illustrating an example of a diffuser;

FIG. 2 is a diagram illustrating an example of how a diffuser can sample plans by iteratively denoising two-dimensional arrays, according to aspects of the disclosure;

FIG. 3 is a diagram illustrating an example of a learned long-horizon planning diffuser operation, according to aspects of the disclosure;

FIG. 4 is a diagram illustrating how diffusion models will perform a forward diffusion process and a reverse denoising process, according to aspects of the disclosure;

FIG. 5 is a diagram illustrating an example of planning with diffusion models that shows a coupling between modeling and planning, according to aspects of the disclosure;

FIG. 6 is a diagram illustrating an example of how to exploit symmetries in geometric structures, according to aspects of the disclosure;

FIG. 7 is a diagram illustrating an example of how to generate a trained equivariant diffusers, according to aspects of the disclosure;

FIG. 8A is a diagram illustrating an example method associated with using symmetry of geometric structures, according to aspects of the disclosure;

FIG. 8B is a diagram illustrating another example method associated with using symmetry of geometric structures, according to aspects of the disclosure;

FIG. 9A is a diagram illustrating an example of a geometric U-Net which can treat state-action trajectories as images, according to aspects of the disclosure;

FIG. 9B is a diagram illustrating an example of a geometric U-Net which can treat state-action trajectories as images, according to aspects of the disclosure;

FIG. 10 is a diagram illustrating an example of state decompositions, according to aspects of the disclosure;

FIG. 11 is a diagram illustrating an example of equivariant trajectory generation, according to aspects of the disclosure;

FIG. 12A is a diagram illustrating an example use related to robotics, according to aspects of the disclosure;

FIG. 12B is a diagram illustrating an example use related to robotics showing trajectories generated by the equivariant diffuser model, according to aspects of the disclosure; and

FIG. 13 is a diagram illustrating an example of a computing system, according to aspects of the disclosure.

### DETAILED DESCRIPTION

Certain aspects of this disclosure are provided below. Some of these aspects may be applied independently and some of them may be applied in combination as would be apparent to those of skill in the art. In the following description, for the purposes of explanation, specific details are set forth in order to provide a thorough understanding of aspects of the application. However, it will be apparent that various aspects may be practiced without these specific details. The figures and description are not intended to be restrictive.

The ensuing description provides example aspects only, and is not intended to limit the scope, applicability, or configuration of the disclosure. Rather, the ensuing description of the example aspects will provide those skilled in the art with an enabling description for implementing an example aspect. It should be understood that various changes may be made in the function and arrangement of elements without departing from the spirit and scope of the application as set forth in the appended claims.

Path or route planning with a learned model can be a conceptually simple framework for reinforcement learning and data-driven decision-making. The appeal of route planning with the learned model can come from employing learning techniques only where they are the most mature and effective, such as for the approximation of unknown environment dynamics in what amounts to a supervised learning problem. Afterwards, the learned model may be input to classical trajectory optimization routines, which are similarly well understood in their original context. However, such a combination may not work as desired. For example, because powerful trajectory optimizers may exploit learned models, plans generated using such a procedure may appear more like adversarial examples than optimal trajectories. As a result, contemporary model-based reinforcement learning algorithms often inherit more from model-free methods, such as value functions and policy gradients, than from the trajectory optimization toolbox. Techniques that do rely on online planning tend to use simple gradient-free trajectory optimization routines, like random shooting or the cross-entropy method, to avoid the aforementioned issues.

One approach to data-driven trajectory optimization is to train a model that is directly amenable to trajectory optimization, in the sense that sampling from the model and planning with the model become nearly identical. To achieve such a goal, a shift in how the model is designed may be needed. Because learned dynamics models are normally meant to be proxies for environment dynamics, improvements are often achieved by structuring the model according to the underlying causal process. Instead, some have considered how to design a model in line with the planning problem in which it will be used. For example, because the model will ultimately be used for planning, action distributions may be as important as state dynamics, and long-horizon accuracy may be more important than single-step error. On the other hand, it can be beneficial for the model to remain agnostic to a reward function so that the model may be used in multiple tasks, including those unseen during training. Further, it can be beneficial for the model to be designed so that its plans, and not just its predictions, improve with experience and are resistant to the myopic failure modes of standard shooting-based planning algorithms.

In some cases, a trajectory-level diffusion probabilistic model and a diffuser can be used for planning. While standard model-based planning techniques predict forward in time autoregressively, a “diffuser” or “diffusion model” predicts all timesteps of a plan simultaneously. The iterative sampling process of diffusion models leads to flexible conditioning, allowing for auxiliary guides to modify the sampling procedure to recover trajectories with high return or satisfying a set of constraints. The above formulation of data-driven trajectory optimization has some appealing properties like long-horizon scalability, task compositionality, temporal compositionality, and efficient non-greedy planning. Some approaches are disclosed by Janner et al., Planning with Diffusion for Flexible Behavior Synthesis, Proceedings of the 39^{th} International Conference on Machine Learning, Baltimore, Maryland, 2022, incorporated herein by reference.

Model-based reinforcement-learning methods in the era of deep learning are often underpinned by the availability of an approximate dynamics model, which among other important objectives enables planning. Standard methods often require a large amount of training data to be useful. Some diffusion models demonstrate the advantages of tightly coupling the modeling and planning problem by training a powerful diffusion model on an offline dataset. However, in many real-world applications, such as robotics, the environment includes a geometric structure in the form of symmetries. The symmetries of the environment are not exploited explicitly in the current diffusion model. When a standard model is used to approximate the dynamics of robotic movement or other tasks, large amounts of data are needed for training for the model to be ultimately useful. The systems and techniques described herein extend the application of diffusion models used in planning with equivariance constraints based on the SE(3) group (Special Euclidean group with 3 elements) symmetries which leads to a group-invariant density over trajectories leading to gains in sample efficiency, training speed, and model generalizability.

In general, equivariance refers to taking into account symmetries of the world, such as rotations, reflections, and/or translations of a state space and utilizing those symmetries. One reason to exploit symmetries is that the world is filled with symmetries. The laws of physics are the same everywhere in space and time. For example, it is known that gravity causes objects to move up or down in a particular direction. In many cases, the laws of physics are symmetric under translations and rotations of spatial coordinates, as well as under time shifts with respect to objects, such as robots or objects that can be manipulated by robots. These symmetries are also present in many dynamic environments. For example, a robotic gripper may often move an object from left to right in a similar way as the gripper would move an object from top to bottom. Likewise, the navigation patterns of a quadruped are independent of whether it is moving East or North.

Systems and techniques are described herein that introduce a planning algorithm that incorporates a symmetry structure of an environment. The inductive bias based on geometric symmetries improves the sample efficiency and generalization performance. Rather than needing to approximate all the dynamics of movement of a robot, for example, by exploiting the symmetry of its movement or known physical characteristics of the environment, less training data will be needed to generate the model. A benefit of incorporating the known symmetries of the world can improve training models as less data is required. The training process can leverage the prior knowledge of the environment with respect various symmetries to improve the training process.

In some aspects, the disclosed systems and techniques are based on a diffuser method as introduced herein. For example, the diffuser method can unify or address the problem of learning a world model and the problem of planning, in the world model, separate steps using conventional model-based reinforcement learning (RL). The diffuser model approach can be based on treating model planning as a generative modelling problem. Other approaches train a diffusion model of state-action trajectories on an offline dataset. By conditioning such a diffusion model on initial and final states, the systems and techniques can generate behaviors that bring an agent (e.g., a system or device, such as a vehicle, a robotics system or device, a drone, etc.) from one state into another. In addition, the systems and techniques can generate samples that maximize any reward function by sampling from a model with classifier guidance. For example, the classifier guidance can provide rewards at one or more states in a particular trajectory, which can be maximized to determine an optimal final trajectory to complete a task. A trajectory can refer to sequence of states and actions that a system or device (e.g., a vehicle, a robotics device, a drone, etc.) may encounter.

The systems and techniques described herein can result in strong performance on long-horizon problems and high flexibility at test time. In some cases, the original diffuser approach can still require a large amount of training data, which may be due to the lack of inductive bias about the symmetry structure of certain problems. In some aspects, the systems and techniques provide an equivariant diffuser, which is a planning algorithm based on a SE(3)× [symbol] ×Sₙ invariant diffusion model of trajectories. SE(3) can represent the symmetry of spatial translations and rotations SE(3). [symbol] can represent the discrete time translation symmetry, and Sₙ can represent the permutation group over n objects. The invariance constraint can be enforced through an invariant base density and an equivariant denoising network.

The solutions provided by the systems and techniques disclosed herein can apply to different settings, such as offline reinforcement learning, model-based reinforcement learning, and trajectory generation. In some aspects, the systems and techniques can combine principles of equivariant deep learning, diffusion models, and planning with deep learning. In some cases, the systems and techniques can pre-plan an entire trajectory (e.g., including a sequence or series of states and actions) for a system or device, such as for a robotics system to pick up and move an object. Various types of systems or devices can implement the systems and techniques, such as robotic arms or hands, quadrupeds or bipeds, a robotic vacuum cleaner, a vehicle (e.g., an autonomous or semi-autonomous vehicle), a drone, etc. Various tasks can be implemented using the systems and techniques, such as object manipulation (e.g., picking up and placing objects, surgery, etc.), locomotion or navigation of a system or device, among others. As noted above, one basic property of geometric structure is leveraged such as SE(3) symmetries in that the world (or the robot or other environment) behaves similarly at different positions in space. In some aspects, there can be permutation symmetries where a system or device (e.g., a robotics system) should behave the same when interacting with various similar objects.

Additional aspects of the present disclosure are described in more detail below with respect to the figures.

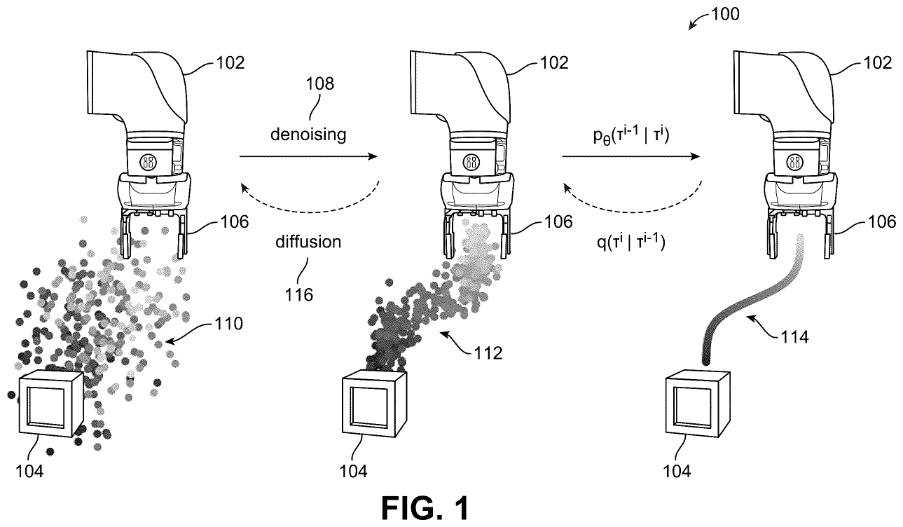

FIG. 1 illustrates an environment 100 in which a diffuser can be applied. The diffuser can plan a route by iteratively refining trajectories. As noted above, planning with a learned model is a basic framework for reinforcement learning and data-driven decision-making. The approach employs learning techniques for the approximation of unknown environment dynamics in what amounts to a supervised learning problem. Afterwards, the learned model may be input to classical trajectory optimization routines. However, because powerful trajectory optimizers exploit learned models, routes planned using such optimizers may be problematic because the resulting routes may appear more like adversarial examples than optimal trajectories. Standard model-based reinforcement learning algorithms may inherit more from model-free methods, such as value functions and policy gradients, than from the trajectory optimization data. Relying on online planning tends to use gradient-free trajectory optimization routines like random shooting or the cross-entropy method to avoid problematic issues. The standard approach of planning with diffusion for flexible behavior synthesis was developed to address these issues, but still require too much data for training and are not easily generalizable to new tasks or trajectories.

In FIG. 1, the environment 100 includes a structure 102 (e.g., a robotic arm or other structure) with a receiving component 106 that can receive an object 104 (e.g., a box), such as by grasping the object 104. The environment 100 illustrated in FIG. 1 provides an example of the structure 102 performing a task (e.g., picking up the object 104) that may follow one or more trajectories. For example, trajectory points 110 are shown that collectively represent an original trajectory of the structure 102. Each of the trajectory points 110 represent a state based on an action (e.g., a position of the structure 102 based on a particular movement of the structure 102). The original trajectory can have many different states based on a diffused or noisy environment in which the structure 102 can move to many different possible points along a trajectory in order to receive the object 104 (e.g., grasp the object 104). Based on performing a denoising 108 flow, the model can iteratively refine the trajectory such that, in a new state represented by trajectory points 112, the trajectory becomes more focused or refined. The trajectory can be further refined as shown by trajectory points 114 in further iterations. An opposite flow can cause diffusion 116 in which a more specific trajectory (e.g., the trajectory represented by trajectory points 114 or the trajectory represented by trajectory points 112) can be diffused and become random.

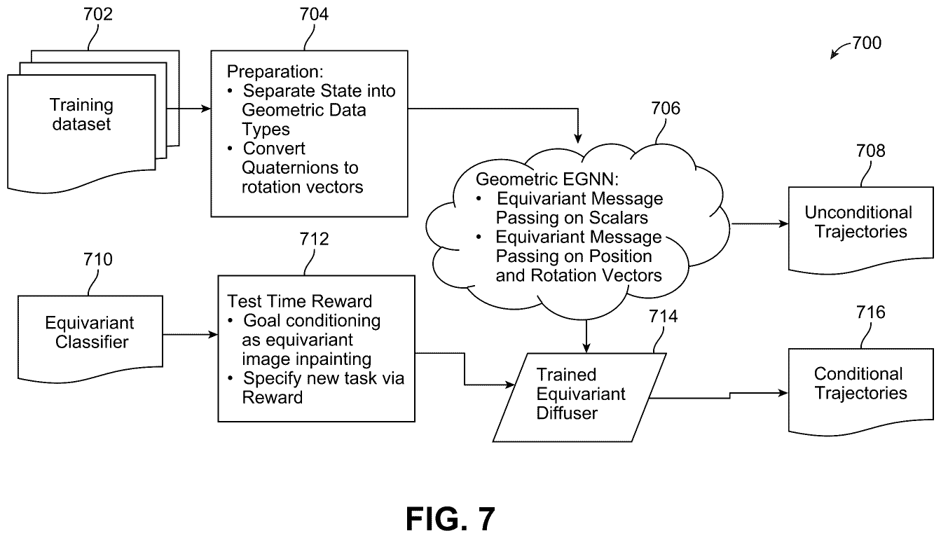

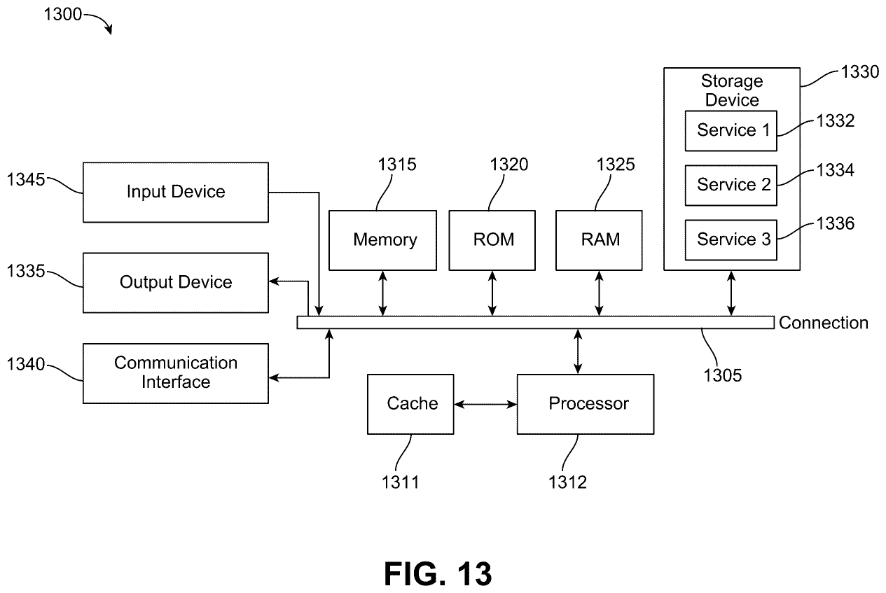

The diffuser approach to data-driven trajectory optimization includes the core idea to train a model that is directly amenable to trajectory optimization, in the sense that sampling from the model and planning with it become nearly identical. Learned dynamics models are normally meant to be proxies for environment dynamics. With diffusion models, the approach considers how to design a model in line with the planning problem in which it will be used. As noted above, the current disclosure introduces the idea of solving the problems associated with traditional diffusion models by using an equivariant diffusion model. An example apparatus for using diffusion models using symmetries in geometric structures can include at least one memory (e.g., a memory configured in circuitry such as one or more of system memory 1315, memory 1320, 1325 and/or cache 1311 of FIG. 13 described below) and at least one processor (e.g., processor 1312 of FIG. 13) coupled to the at least one memory and configured to: receive, via a training preparation engine 704 (e.g., engine of FIG. 7 described below), a training dataset (e.g., training dataset 702 of FIG. 7) including state-action pairs; separate, via the training preparation engine, the state-action pairs from the training dataset into geometric data types; convert, via the training preparation engine, the geometric data types into internal representations; process, via an equivariant denoising network (e.g., equivariant diffuser 714 of FIG. 7), the internal representations to generate output data; and transform the output data to a data representation. Further details regarding such an apparatus and associated methods are introduced below.

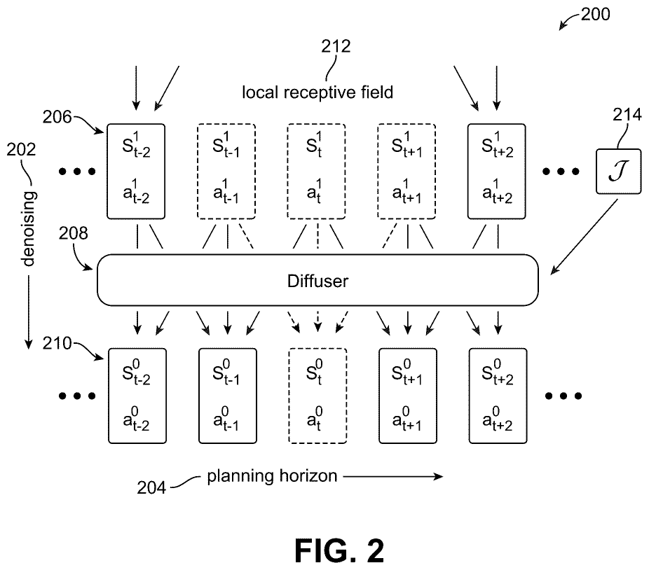

FIG. 2 illustrates blocks and components 200 that show various inputs 206 and outputs 210 of a diffuser model or diffuser 208. The trajectory-level diffusion probabilistic model can be called a diffuser or diffuser model. Whereas standard model-based planning techniques predict forward in time autoregressively, the diffuser 208 predicts all timesteps of a plan simultaneously as shown by the outputs 210. The iterative sampling process of the diffuser 208 leads to flexible conditioning, allowing for auxiliary guides to modify the sampling procedure to recover trajectories with high return or satisfying a set of constraints. Denoising 202 occurs from top to bottom in FIG. 2, and the planning horizon 204 can operate from left to right in time. The diffuser 208 samples plans by iteratively denoising 202 two-dimensional arrays including a variable number of state-action pairs. A small receptive field 212 constrains the model to only enforce local consistency during a single denoising step. By composing many denoising steps together, local consistency can drive global coherence of a sample of the planning horizon 204. An optional guide function ℑ 214 can be used to bias plans toward those optimizing a test-time objective or satisfying a set of constraints.

The above-described formulation of data-driven trajectory optimization has various appealing properties. For example, to achieve long-horizon scalability, the diffuser 208 can be trained for the accuracy of its generated trajectories rather than its single-step error, so the diffuser 208 does not suffer from the compounding rollout errors of single-step dynamics models and scales more gracefully with respect to long planning horizon. To achieve task compositionality, the reward functions provide auxiliary gradients to be used while sampling a plan, allowing for a straightforward way of planning by composing multiple rewards simultaneously by adding together their gradients. Temporal compositionality can be achieved when the diffuser 208 generates globally coherent trajectories by iteratively improving local consistency, allowing the diffuser 208 to generalize to novel trajectories by stitching together in-distribution subsequences. Finally, effective non-greedy planning is achieved by blurring the line between model and planner, and the training procedure that improves the model's predictions also has the effect of improving planning capabilities of the diffuser 208. Such a design yields a learned planner that can solve the types of long-horizon, sparse-reward problems that prove difficult for many conventional planning methods.

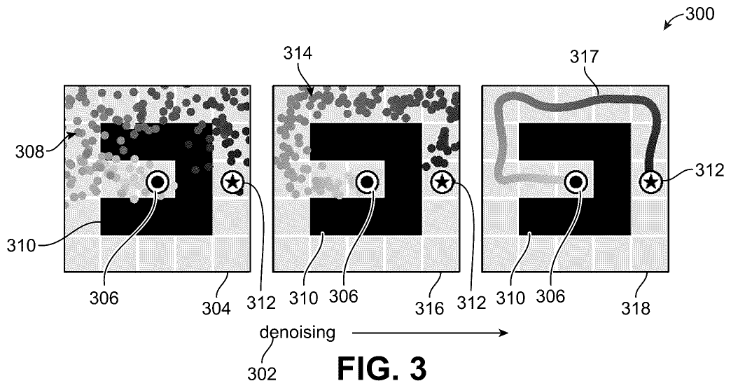

FIG. 3 illustrates a graphic representation 300 of the learned long-horizon planning property of diffusion planners or diffuser 208. As shown, three different states such as a first state 304, a second state 316, and a third state 318 of a trajectory are associated with moving a robot or other device from a first point 306 to a destination 312. In the first state 304, there are many random states or locations (e.g., location 308) where the device can move. These random states or locations can be added by a training engine (e.g., training preparation engine 704 of FIG. 7). A wall or barrier 310 might require navigation to arrive at the destination 312. Through the denoising process 302, the system can iteratively move to a next state corresponding to trajectories 314 shown in a more defined path, as illustrated in the second state 316. The trajectories 314 are tighter and become less random. The third state 318 illustrates a more defined path or trajectory 317 relative to the trajectory 314 shown in the second state 316. The system can include a neural network which performs the denoising process, where at each iteration of the neural network, the trajectory (e.g., trajectory 314 or 317) becomes less noisy until the clear trajectory 317 of the defined path, as is shown in the third state 318, is achieved. The process can include calling the neural network and calling a rewards function to get a sequence of states and actions that achieves the task with the proper maximized rewards.

Single-step models are typically used as proxies for ground-truth environment dynamics ƒ, and as such are not tied to any planning algorithm in particular. In contrast, the planning routine in a diffusion planning algorithm can be closely tied to the specific affordances of the diffuser 208. Because a planning method is nearly identical to sampling (with the only difference being guidance by a perturbation or rewards function r(τ)), a diffuser's effectiveness as a long-horizon predictor directly translates to effective long-horizon planning. There are benefits of learned planning in a goal-reaching setting with the example shown in FIG. 3, showing that the diffuser 208 is able to generate feasible trajectories in the types of sparse reward settings where shooting-based approaches are known to struggle.

The denoising diffusion model or the diffuser 208 is designed for trajectory data and an associated probabilistic framework for behavior synthesis. While unconventional compared to the types of models routinely used in deep model-based reinforcement learning, the diffuser 208 has a number of useful properties and is particularly effective in offline control settings that require long-horizon reasoning and test-time flexibility. Systems and techniques are described herein for improving the diffuser 208 to further take advantage of symmetries associated with geometric structures particularly with application to robotics although other environments are envisioned as within the scope of this application.

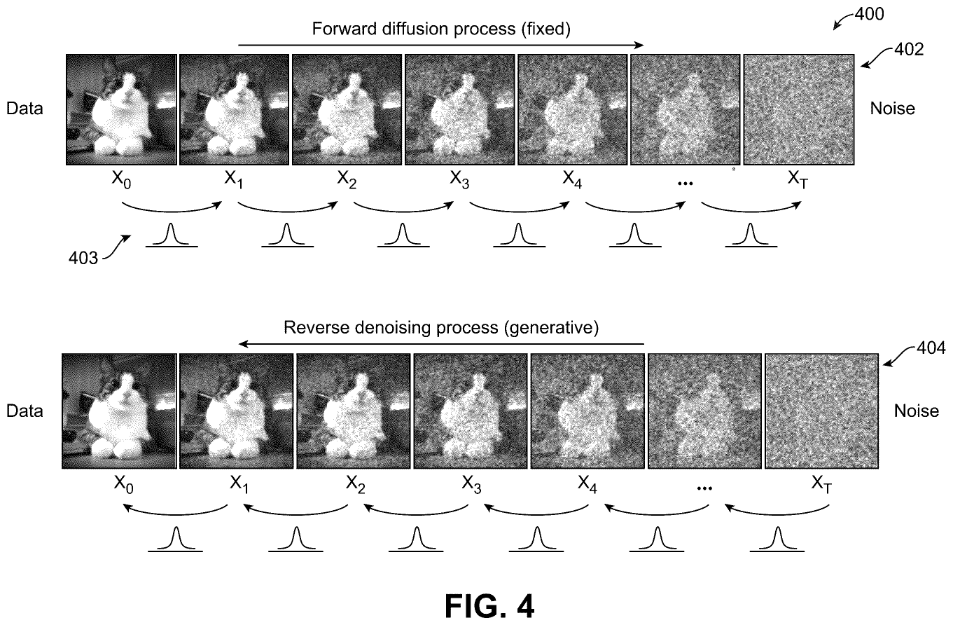

FIG. 4 provides two sets of images 400 that show the forward diffusion process (which is fixed) and the reverse diffusion process (which is learned) of a diffusion model. As shown in the forward diffusion process of FIG. 4, noise 403 is gradually added to a first set of images 402 at different time steps for a total of T time steps (e.g., making up a Markov chain), producing a sequence of noisy samples X₁ through X_{T}.

Diffusion models from a training perspective will take an image and will slowly add noise to the image to destroy the information in the image. In some aspects, the noise 403 is Gaussian noise. Each time step can correspond to each consecutive image of the first set of images 402 shown in FIG. 4. The initial image X₀ of FIG. 4 is of a cat. Addition of the noise 403 to each image (corresponding to noisy samples X₁ to X_{T}) results in gradual diffusion of the pixels in each image until the final image (corresponding to sample X_{T}) essentially matches the noise distribution. For example, by adding the noise, each data sample X₁ through X_{T} gradually loses its distinguishable features as the time step becomes larger, eventually resulting in the final sample X_{T} being equivalent to the target noise distribution, for instance a unit variance zero-centered Gaussian [symbol] (0, 1).

The second set of images 404 shows the reverse diffusion process in which X_{T} is the starting point with a noisy image (e.g., one that has Gaussian noise). The diffusion model can be trained to reverse the diffusion process (e.g., by training a model p_{θ}(xₜ₋₁|xₜ)) to generate new data. In some aspects, a diffusion model can be trained by finding the reverse Markov transitions that maximize the likelihood of the training data. By traversing backwards along the chain of time steps, the diffusion model can generate the new data. For example, as shown in FIG. 4, the reverse diffusion process proceeds to generate X₀ as the image of the cat. In other cases, the input data and output data can vary based on the task for which the diffusion model is trained.

As noted above, the diffusion model is trained to be able to denoise or recover the original image X₀ in an incremental process as shown in the second set of images 404. In some aspects, the neural network of the diffusion model can be trained to recover Xₜ given Xₜ₋₁, such as provided in the below example equation:

$$q ( {x}_{t} \vert {x}_{t - 1} ) = 𝒩 ( {x}_{t} ; \sqrt{1 - {β}_{t}} {x}_{t - 1} , {β}_{t} I )$$

A diffusion kernel can be defined as:

$$Define {\hat{∝}}_{t} = {\prod }_{s = 1}^{t} ( 1 - {β}_{s} ) \qquad \to \qquad q ( {x}_{t} \vert {x}_{0} ) = 𝒩 ( {x}_{t} ; \sqrt{{\hat{∝}}_{t}} {x}_{0} , ( 1 - {\hat{∝}}_{t} ) I )$$

Sampling can be defined as follows:

$$\begin{matrix}{x}_{t} = \sqrt{{\hat{∝}}_{t}} {x}_{0} + \sqrt{1 - {\hat{∝}}_{t}} & ε & where ε ∼ 𝒩 ( 0 , I )\end{matrix} .$$

In some cases, the βₜ values schedule (also referred to as a noise schedule) is designed such that \hat{∝}_{T}→0 and q(x_{T}|x₀)≈ [symbol] (x_{T}; 0, I).

The diffusion model runs in an iterative manner to incrementally generate the input image X₀. In some examples, the model may have twenty steps. However, in other examples, the number of steps can vary.

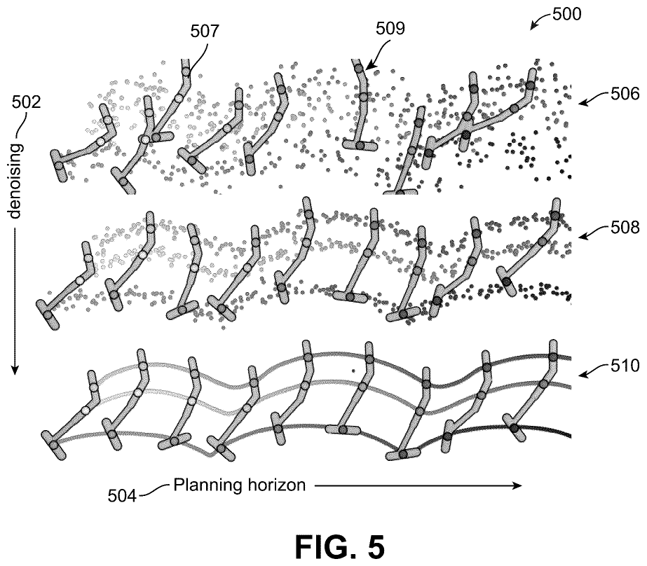

FIG. 5 illustrates a graph 500 showing planning with diffusion models. The Y or vertical axis can represent from top to bottom the denoising process 502 starting with a first set of images 506 that are quite noisy. The graph 500 can represent a set of state-action pairs which can have random noise added. The first set of images 506 can also represent by way of example a series of physical objects, such a robotic arm and potential movement of joints 507 or joint angles within the robotic arm 509 represented by the different points in the first set of images 506.

Robot states may be specified through a collection of joint angles. For instance, one of the joint angles can encode the rotation of the base along the vertical z-axis. An angle can be represented as a ρ₁ vector in the xy-plane. In addition, the gravity direction (the z-axis itself) can be added as another ρ₁ vector, which is also the normal direction of a surface (e.g., a table) on which one or more objects (e.g., n objects) rest. Combined, these vectors define the pose of the base of the robot arm. Rotating the gravity direction and the robot and object poses by SO(3) can be interpreted as a passive coordinate transformation, or as an active rotation of the entire scene, including gravity. SO(3) refers to a “special orthogonal” group with three dimensions. Such a solution provides valid symmetry, as the laws of physics are invariant to the transformation.

The n objects can be translated and rotated. Their pose can is thus given by a translation t∈ [symbol] ³ and rotation in r∈SO(3) relative to a reference pose. The translation transforms by a global rotation g∈SO(3) as a vector via representation ρ₁. The rotational pose transforms by left multiplication r [symbol] gr. The SO(3) pose is not a Euclidean space, but a non-trivial manifold. Even though diffusion on manifolds is possible, the techniques described herein can simplify the problem by embedding the pose in a Euclidean space. The embedding can be done by picking the first two columns of the pose rotation matrix r∈SO(3). The columns can each be transformed as a vector with representation ρ₁, which forms an equivariant embedding ι: SO(3) [symbol] [symbol] ^{2×3}, whose image are two orthogonal 3-vectors of unit norm. Via the Gram-Schmidt procedure, an equivariant map π: [symbol] ^{2×3}→SO(3) can be defined, which is a left inverse to the embedding: π∘ι=id_{SO(3)}. Combining with the translation, the roto-translational pose of each object is thus embedded as three ρ₁ vectors.

Noise can be added in the trajectory to then enable the denoising process. The noise, for example, might be Gaussian noise. The X or horizontal axis from left to right can represent the planning horizon 504. The planning horizon 504 can be a particular amount of time. The second set of images 508 shows a more refined and less noisy positioning of the physical objects as well as the different points between them. the (final) third set of images 510 can show a denoised representation of the physical object and the movement or actions of the joints of the physical object. The graph 500 can illustrate a tighter coupling between modeling and planning where a function f(τ) can represent a diffusion model and another function like r(τ) can represent some auxiliary information such as a corollary to the rewards function described below and the final function is the product of these two other functions as p(τ)=f(τ)r(τ). Here, τ is a trajectory or a series of states and actions. FIG. 5 illustrates how, from a noisy input, the model can guide the process to a valuable output or plan.

Incorporating symmetry structures into robotic planning can have several aspects. First, the architecture can support the various ways in which properties of the system can behave under the symmetry. Robot and object properties can usually be divided into scalar, vector, and quaternionic representations of SE(3) (Special Euclidean group with 3 elements). The latter are for instance used to parameterize orientations of three-dimensional objects. The techniques described herein include using equivariant networks for scalar and vector representations and introduces a novel equivariant treatment of quaternionic data. The training data in some aspects can be tagged based on a geometric data type (e.g., scalars, vectors, quaternions) and those tags can be used to cause a neural network to process the data to take advantage of symmetries of the environment and according to the tags which can maintain equivariance as described herein.

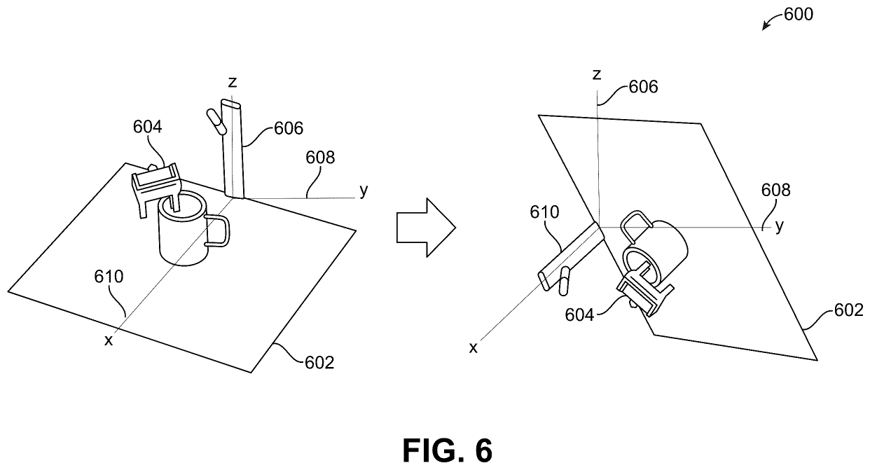

FIG. 6 is a diagram 600 illustrating an example of how to exploit symmetries in geometric structures. The diffusion model used herein is a specific type of neural network. The approach is to prescribe or prespecify a mathematical group which describes how an object will transform under certain actions within its environment. For example, a ball in a three-dimensional environment can be moved or flipped over on its axis, or the ball can be translated to a new location, which are actions that can have some known valid symmetrical results which can be exploited in the modeling process. The model can provide a “density,” which provides a probability of the states in the space, and can sample from that density, and the system can determine a likely trajectory. If there is a given trajectory, a probability can be associated with that trajectory. A group-invariant density can mean that no matter what happens to the object, the object should have the same likelihood or probability of actually happening.

The system can “bake” into the model the group-invariant density and the associated probabilities. The diagram 600 shows a robotic arm 604 and a table 602 that exhibit SE(3) symmetries. In a first system, the table 602 and the robotic arm 604 are shown in a coordinate system, such as the XYZ cartesian coordinate system that includes an x axis 610, a y axis 608, and a z axis 606. In the first system, the robotic arm 604 is shown along the Z axis 606. The first system can be rotated such that the robotic arm 604 is configured or aligned along the X axis 610 of the coordinate system. A group invariant density satisfies p(g*τ)=p(τ) for all g in G. A group can be all possible rotations or all possible reflections associated with an environment. In some examples, a group can also refer to symmetric actions where things are expected to stay the same. The group is the mathematical concept in which a set of different rotations such as rotating a little, rotating a lot, or any combinations of rotation. A combination of various groups can be in the SE(3) environment. In some cases, a sufficient condition is to build group-invariant diffusion models f(τ) with a group-equivariant neural network. The approach disclosed herein does not require tasks to respect the symmetry. The system can sample from non-invariant trajectory rewards r(τ). When the information is available, the system can indicate to the robot that the trajectories that can be reflections of each other are all actually the same where symmetries apply, which can improve the efficiency of the system.

In some aspects, a robot can be trained on data where a robotic arm moves a glass from a left side of a table to the right side of the table. The robot would typically not be able to perform new tasks like moving the glass from the right side to the left side of the table, or to pick the glass up from the ground and lift it up to the table. The approach here takes into account that there are symmetries in these movements (right to left or down to up) that correspond to the trained movement of moving the glass from left to right on the table. The neural network can utilize the symmetry of the world to know that the neural network can move the glass from right to left or from the floor to the table, based on training in one task of moving the glass from left to right but has some symmetric relationship to additional tasks for which the robot is not specifically trained.

A second aspect is to properly support test-time symmetry dividing or breaking. Even when environments exhibit symmetries, concrete tasks usually divide or break these symmetries, for instance when a robot has to move an object to a specific point in space. The disclosed approaches allow for the test-time dividing or breaking of the symmetry group through the task specification.

Diffusion models are further discussed next. Diffusion models can include two processes. The first one, dubbed the diffusion process, starts from a clean data sample x˜q(x₀) and progressively injects noise (e.g., Gaussian noise) at every time step i∈[T] until a terminal step T where the resulting sample includes pure noise. See FIG. 4 for an example of the forward diffusion process. The reverse generative process takes a sample from a noise distribution and denoises the sample by progressively adding back structure until the images (e.g., or the robotic tasks) return to a sample that resembles being drawn from the empirical data distribution p(x).

Trajectory optimization with diffusion is another concept disclosed herein. Systems can be modeled that are governed by discrete-time dynamics of a state sₜ₊₁=f(sₜ, aₜ), given the state sₜ and action aₜ taken at timestep t. The function can be trained to perform different tasks at different states to perform a next operation in a next time based on observed conditions. The system uses the geometry of the environment to achieve the particular reward. A goal in trajectory optimization is to then find a sequence of actions a*_{0:T} that maximizes an objective (e.g., a reward) ℑ which factorizes over per-timestep rewards r(sₜ, aₜ). Such a technique can correspond to the following optimization problem shown in equation (1):

$${a}_{0 ; T}^{*} = arg {max}_{{a}_{0 ; T}} 𝒥 ( {s}_{0} , {a}_{0 : T} ) = arg {max}_{{a}_{0 ; T}} {\sum }_{t = 0}^{T} r ( {s}_{t} , {a}_{t} ) , \qquad ( 1 )$$

Here, T is the planning horizon (e.g., the number of steps such as one hundred steps) and the system makes use of the abbreviation τ=(s₀, a₀, . . . , a_{sT}, a_{T}) to denote the trajectory. The “τ” value is trajectory, and T is how long the trajectory is. Then “a” values are the actions taken by a robot, for example, such as move a certain amount, or pick up an item, at a specific time or state. So at state “0,” the robot takes action “0”. Based on that action, a new state “1” is experienced, the robot may observe a new wall, or a different environment, because the robot has moved. Then action “1” is taken based on state “1.” A chain graph can be used as a modeling choice for modeling the trajectory, but other approaches can be used as well. The “r” function in equation (1) is the reward. The reward may occur at various points along the path of the robot. Equation (1) seeks to maximize the set of rewards that are provided along the path at each state and each action. At each state, a separate reward might be provided, and thus the a*_{0:T} value can be the maximum of the various pathways along the trajectory that provides the highest reward. The system may provide a +1 reward if the robot arrives at a destination or successfully picks up an object. In the example of FIG. 3, the goal is to move a robot from a first point 306 around a barrier 310 to a destination 312, which can be a final destination. The reward is successfully navigating to the destination 312.

A practical method to solve a trajectory optimization problem is to subsume the planning process within a diffusion model. In particular, the systems and techniques described herein can decouple learning the approximate dynamics f and trains a powerful diffusion model using offline data and then treats planning as a conditional sampling problem when given auxiliary information in the form of a reward. For example, the systems and techniques can learn a diffusion model p_{θ}(τ) over trajectories which can be reused for different tasks in the following way shown in equation (2):

$${\tilde{p}}_{θ} ( τ ) ∝ {p}_{θ} ( τ ) h ( τ ) , \qquad ( 2 )$$

Here, h(τ) can represent any prior evidence, desired outcomes (e.g., goal conditioning), or rewards in general, which can relate to the rewards function r(τ) discussed herein.

The representation of trajectories can play a role as the diffusion model informs the design space of models that can be leveraged to solve the trajectory optimization problem. In the previous use of diffusion models, each trajectory can be thought of as an image with a single channel where the width is the planning horizon T, and each column in the height corresponds to a concatenation of states and actions at a particular timestep (sₜ, aₜ) flattened as a vector. Specifically, the inputs and outputs of the diffuser architecture are given by the following two-dimensional array:

$$τ = [ \begin{matrix}{s}_{0} & {s}_{1} & ⋯ & {s}_{T} \\ {a}_{0} & {a}_{1} & ⋯ & {a}_{T}\end{matrix} ] . \qquad ( 3 )$$

A benefit of considering such a trajectory representation is that it makes simple the application of diffusion models over images to the RL setting. In addition, with a variable planning horizon, it is possible to generate variable length trajectories by simply sampling noise of the same dimensionality.

An equivariant diffuser algorithm introduced herein includes an invariant diffusion model for state-action trajectories τ=(s₀, a₀, . . . , s_{T}, a_{T}). The invariant diffusion model includes an invariant base density and an equivariant denoising network. The network can be trained following the standard training algorithm for diffusion models: by adding noise to trajectories, feeding them into the denoising network, and training the network to predict the original trajectory (or, equivalently, the added noise).

After training, the model can be used to sample trajectories unconditionally, to sample trajectories conditionally on initial and goal states, and to sample trajectories with classifier guidance to solve a task specified at test time.

The symmetry group and representations, the equivariant architecture of the denoising network, the network training, and the unconditional and conditional sampling at test time are now discussed in more detail with reference to FIG. 7. FIG. 7 is a flow diagram 700 illustrating how to use symmetry to train and utilize the network. The flow diagram 700 relates generally to using a representation of trajectories as a chain graph in time. However, as noted elsewhere herein, the use of a chain graph is a modeling choice and thus other approach are contemplated as well.

A training dataset 702 can be prepared by separating states or each state into geometric data types and converting quaternions to rotation vectors. The states can include a state of a robot arm angle, an object, its location, etc. A training preparation engine 704 can perform these operations on the training data set 702. A symmetry group SE(3)× [symbol] ×Sₙ can be considered which is a product of three distinct groups: (1) the symmetry of spatial translations and rotations SE(3), (2) the discrete time translation symmetry Z, and the permutation group over n objects Sₙ. The states can include, for example, joint angles for a robot, or how an object is presented such as its position or its orientation in the environment (represented by quaternions), and so forth. In some aspects, an object may have a color. The system may include such data as a scalar value that does not change with rotation or movement. The color in other words would not change with movement or rotation of an object.

The symmetry group may be divided (e.g., softly broken) in an environment. For example, the symmetry group can be divided into at least one smaller group based on some condition. The dividing of the symmetry group can also be characterized as breaking the symmetry group. For instance, the direction of gravity often divides or breaks the spatial symmetry SE(3) to the smaller group SE(2), and distinguishable objects break the permutation group. The philosophy of modeling invariance can be applied with respect to the larger group and including any symmetry-breaking or symmetry-dividing effects as part of the data.

Any observable object which can be rotated with symmetry can be characterized by how it transforms under the symmetry group. For example, adjustments in data representations can be made in preparation for further processing by the network. Spatial positions can be expressed relative to some key object, for instance the position of the base of a robot or the center of mass. Such a structure guarantees equivariance with respect to spatial translations: to achieve SE(3) equivariance, the system only needs to design an SO(3)-equivariant architecture. As noted previously, SO(3) refers to a “special orthogonal” group with three dimensions.

The transformation under rotations (e.g., using the SO(3) as a subgroup of SE(3) and including a three dimensional rotation group) can be relevant for the disclosed architectural construction. In some aspects, the SO(3) is the group of all rotations about the origin of three-dimensional Euclidean space [symbol] ³ under the operation of composition. The approach allows for features in the following SO(3) representations or tags: (1) Scalars: features s that remain invariant under a rotation R, s→ρₜᵣᵢᵥᵢₐₗ(R)s=s (Examples include angles between two robot joints); (2) Vectors: features in the standard representation of SO(3), v→ρₗ(R)v=Rv (Examples include position or velocity vectors); and (3) Quaternions: features that transform in the quaternionic representation, q→ρ_{q}(R)q=q_{R}∘°q, where q_{R} is the quaternion representation of the rotation matrix R and ∘ is the Hamilton product of quaternions. Examples include object orientations. It can be assumed that all trajectories transform under the regular representation of the time translation group.

Under the permutation group, object properties permute, while robot properties or global properties of the state remain invariant. Each feature is thus either in the trivial or the standard representation of Sₙ.

The training preparation engine 704 can further separate or tag each state-action pair (sₜ, aₜ) into SO(3) scalars s_{toc}∈ [symbol] , SO(3) vectors v_{toc}∈ [symbol] ³, and SO(3) quaternions q_{toc}∈ [symbol] ⁴. These can be determined or characterized as tags which can be used by an equivariant network 706 for message passing between nodes. The different tags (e.g., a scalar, a vector, a quaternion) have different transformations, and the approach is to transform input data in an equivariant manner. For example, if the system applies the transformation to the input data type, the input data should transform in the same way if the system did not initially apply the transformation but applied a function and thereafter applied the group transformation. Different transformation groups apply different laws and thus are each treated differently by the neural network such as the equivariant network 706. Thus, knowing the tags tells the equivariant network 706 which part of the data to process according to the separated geometric data types. Here the indices t, o, c label trajectory time step, object, and channel separately. The value o=∅ can be used to denote global features not associated with any objects (invariants under the permutation group). The channel index c distinguishes multiple features of the same representation in the dataset.

The transformation can generate an internal representation of the data for use by the network. To construct an equivariant network that supports these representations, it will be useful to define a new representation that is used internally in the network. Such features w_{toc}∈ [symbol] ⁴: (1) transform in the regular representation under time shift; (2) transform in the standard representation under w_{toc}Δw_{to′c}=ΣₒP_{o′o} w_{toc} under permutations; and (3) transform in the direct sum of the scalar and the vector representation of SO(3):

$${w}_{toc} = ( \begin{matrix}{s}_{toc} \\ {v}_{toc}\end{matrix} ) \to {w}_{toc}^{′} = ( \begin{matrix}{s}_{toc} \\ {Rv}_{toc}\end{matrix} ) . \qquad ( 4 )$$

The denoising model f maps noisy inputs:

$$τ = \{ {s}^{toc} , {v}^{toc} , {q}^{toc} \} \begin{matrix}i ∈ \{ ∅ , 1 , … , n \} \\ t ∈ \{ 1 , … , T \}\end{matrix}$$

and a diffusion time step i to an estimate of the noise vector used to produce

$$\hat{ϵ} = \{ {\hat{ϵ}}_{toc}^{s} , {\hat{ϵ}}_{toc}^{v} , {\hat{ϵ}}_{toc}^{q} \} .$$

The denoising model f can perform such a technique in at least three steps. First, the data in their various representations are transformed by the training preparation engine 704 into the internal representations introduced above. Next, the representations are processed with an equivariant network 706. The equivariant network 706 can include a geometric equivariant graph neural network (geometric EGNN). Other neural networks, such as those common to computer vision applications, can use the extra geometric tag baked into the network. Models other than a graph neural network can be used as well. In some examples, the trajectories can be represented as a chain graph in time. Other structures can be used as well for the representations of trajectories. The equivariant network 706 can pass equivariant messages on scalars and also can bass equivariant messages on position and rotational vectors. Finally, the output data can be transformed from the internal representation into the data representations.

In some aspects, the training preparation engine 704 can add the noise to the state-action pairs that are in the training dataset 702. The noise can be complete noise, Gaussian noise, or different levels of noise. The training preparation engine 704 can add a little noise, a lot of noise, different types of noise and/or the noise can be added to all the items in the dataset. For example, in FIG. 4, in the bottom half of the generative process can be applied in principle to the training of robots. The system can start with the noisy robot behavior in state X_{T}, and each time neural network processes the input, it can output a slightly less noisy version of the input as the states transition from X_{T}, to X₄ to X₀. The neural network can perform such processing based on the known symmetries of the environment disclosed herein.

The equivariant network 706 can better exploit the symmetries in the geometry of the objects or robots in the environment. Equivariant message passing can be used to pass messages between nodes of the neural network. By passing such messages in the context of a diffusion model (which can be a graph neural net), the neural network can have parts of the network which utilize the message passing concept to maintain constraints to keep the equivariance property consistent such that the outputs are related to the inputs in a certain geometric way. In some cases, an unconditional generative model can generate unconditional trajectories 708 at random in some aspects. At test time, the system can use an equivariant classifier 710 (which can be the r(τ) function or can provide the rewards) which indicates to the system rewards that are possible which can then obtain conditional trajectories. As further shown in FIG. 7, an equivariant diffuser 714 can generate conditional trajectories 716 based on an output from the equivariant classifier 710 and/or a test time rewards engine 712 configured to perform a reward function (e.g., the r(τ) function described above) to improve the generation of a desired trajectory. The equivariant classifier 710 can provide the conditional information for the trajectory generation. The equivariant diffuser 714 can relate to the “f” function discussed above.

A geometric equivariant neural network can include trajectories represented as a chain graph in time in which a geometric graph includes nodes with bi-directional edges at each time step with nodes and features that represent a concatenation of states and actions. The number of nodes in the graph can correspond to the planning horizon T. One benefit of such an approach enables the system to use the information in a natural way. But the use of a chain graph is a modeling choice regarding how to represent the trajectories. Different models can be implemented and the geometric equivariant GNN is a design choice in that other models can be chosen as well for the neural network.

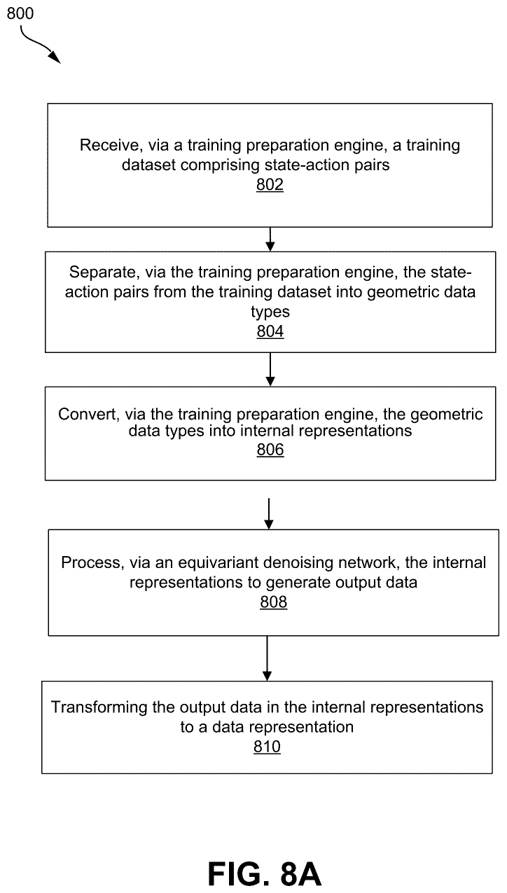

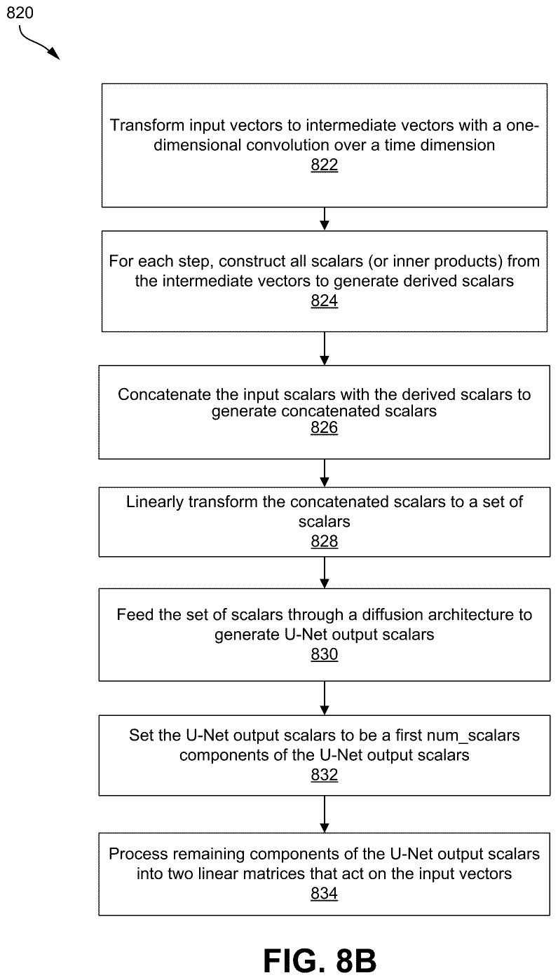

FIG. 8A is a flow diagram illustrating an example of a process 800 for operating an equivariant diffuser or for using a geometric structure for a modeling of tasks. At block 802, the process 800 includes receiving, for example, via a training preparation engine 704, a training dataset including state-action pairs. In some aspects, spatial positions associated with the state-action pairs can be expressed relative to a key object. For example, the key object can include a position of a base of a robot or a center of mass of a robot.

At block 804, the process 800 includes separating, via the training preparation engine, the state-action pairs from the training dataset into geometric data types. In some aspects, the geometric data types can include one or more of scalars, vectors, and quaternions. When the geometric data types include quaternions, the process 800 can include transforming a quaternion of the quaternions into at least two rotation vectors. In some aspects, transforming the quaternion of the quaternions into at least two rotation vectors can include mapping the quaternion to a corresponding element in a matrix representation and selecting two column vectors of the matrix representation as the two rotation vectors. When the data types include scalars, the scalars can be associated with objects corresponding to the state-action pairs.

In some aspects, the separating of the state-action pairs into geometric data types can include or also be characterized as a process of tagging the training data set with tags that identify a geometric data type. Then a neural network can use the tags to process the data in an equivariant way based on the different tags. Different parts of the neural network can be used to process the data based on a respective tag associated with the data, which can ensure that the data is processed in an equivariant way by the neural network. Such a technique enables the system to determine trajectories for new tasks that the system might not be trained on but that be related to the symmetry of the geometric environment associated with the training data.

At block 806, the process includes converting, via the training preparation engine, the geometric data types into internal representations. In some aspects, the internal representations are associated with a symmetry group. In another aspect, the symmetry group can be a product of a number of distinct groups (e.g., three distinct groups). For example, three distinct groups can include a symmetry of spatial translations and rotations group, a discrete time translation symmetry group, and a permutation group over n objects group. In some aspects, the symmetry group can be divided (e.g., softly broken) in an environment and into at least one smaller symmetry group based on a condition. As an example, the condition may be a direction of gravity or an existence of distinguishable objects.

In some aspects, the direction of gravity may break the spatial symmetry group SE(3) to the smaller group SE(2), and distinguishable objects break permutation invariance. The concept can follow the philosophy of modeling invariance with respect to the larger group and including any symmetry-breaking effects as inputs to the networks.

In some aspects, the system may require that spatial positions are always expressed relative to some key object, for instance the position of the base of a robot or the center of mass. Such a requirement can guarantee equivariance with respect to spatial translations: to achieve SE(3) equivariance, the system only need to be implemented as an SO(3)-equivariant architecture.

In some aspects, the symmetry of spatial translations and rotations group relates to representations including one or more of scalars, vectors, and quaternions. In some examples, the scalars can remain invariant under a rotation associated with an angle between two objects. The vectors can be in a standard representation associated with a position or a velocity. The quaternions can be transformed in a quaternionic representation associated with orientation.

In some aspects, converting, via the training preparation engine, the geometric data types into the internal representations can include at least one of transforming a regular representation under a time shift, transforming a regular representation under permutations, or transforming using scalar and vector representations.

At block 808, the process 800 includes processing, via an equivariant denoising network, the internal representations to generate output data. In some aspects, the equivariant denoising network can include alternating types of layers. For example, the alternating types of layers can include one or more of temporal layers, permutation layers, and geometric layers. When the layers include temporal layers, the temporal layers can be one-dimensional convolutions along a trajectory-step dimension. When the layers are permutation layers, the permutation layers can allow features with different objects to interact. When the layers are the geometric layers, the geometric layers can enable mixing between scalar and vector quantities that are combined in the internal representations.

At block 810, the process 800 includes transforming the output data to a data representation. In some aspects, transforming the output data to the data representation can be performed using linear maps. In other aspects, transforming the output data to the data representation using the linear maps can include outputting one scalar for each input scalar, one vector for each input vector, and one scalar and one vector for each input quaternion.

In some cases, the process 800 can further include generating an equivariant diffusion model by combining an invariant base density and the equivariant denoising network. In some aspects, the equivariant diffusion model can be trained by adding noise to the state-action pairs to generate noisy trajectories, feeding the noisy trajectories into the equivariant denoising network, and outputting, using the equivariant diffusion model, one or more predicted original trajectories of the state-action pairs.

The process 800 can further include sampling, using the equivariant diffusion model, trajectories unconditionally. As an alternative, the process 800 can include sampling, using the equivariant diffusion model, trajectories conditionally based on initial goals and states. As another alternative, the process 800 can include sampling, using the equivariant diffusion model, trajectories with guidance from a classifier to solve a task. Sampling trajectories with guidance from the classifier to solve the task can be accomplished using test time rewards and goal conditioning. In another aspect, sampling trajectories with guidance from the classifier to solve the task can include using rewards to specify a new task.

An apparatus for using diffusion models using symmetries in geometric structures can include at least one memory (e.g., a memory configured in circuitry such as one or more of system memory 1315, memory 1320, 1325 and/or cache 1311 of FIG. 13) and at least one processor (e.g., processor 1312 of FIG. 13) coupled to the at least one memory and configured to: receive, via a training preparation engine (e.g., the training preparation engine 704 of FIG. 7), a training dataset (e.g., training dataset 702) including state-action pairs; separate, via the training preparation engine, the state-action pairs from the training dataset into geometric data types; convert, via the training preparation engine, the geometric data types into internal representations; process, via an equivariant denoising network (e.g., equivariant diffuser 714), the internal representations to generate output data; and transform the output data to a data representation.

FIG. 8B illustrates another example process 820 for operating an equivariant diffuser or for using a geometric structure for a modeling of tasks. At block 822, the process 800 includes transforming input vectors to intermediate vectors with a one-dimensional convolution over a time dimension.

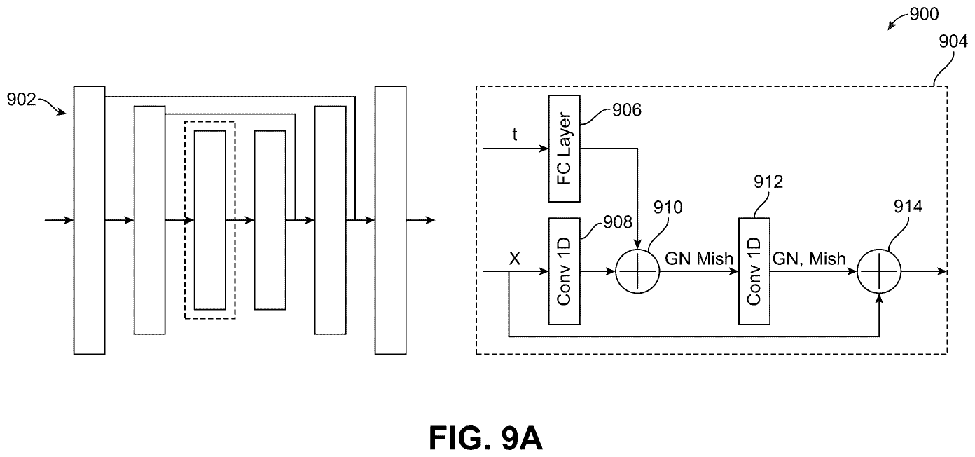

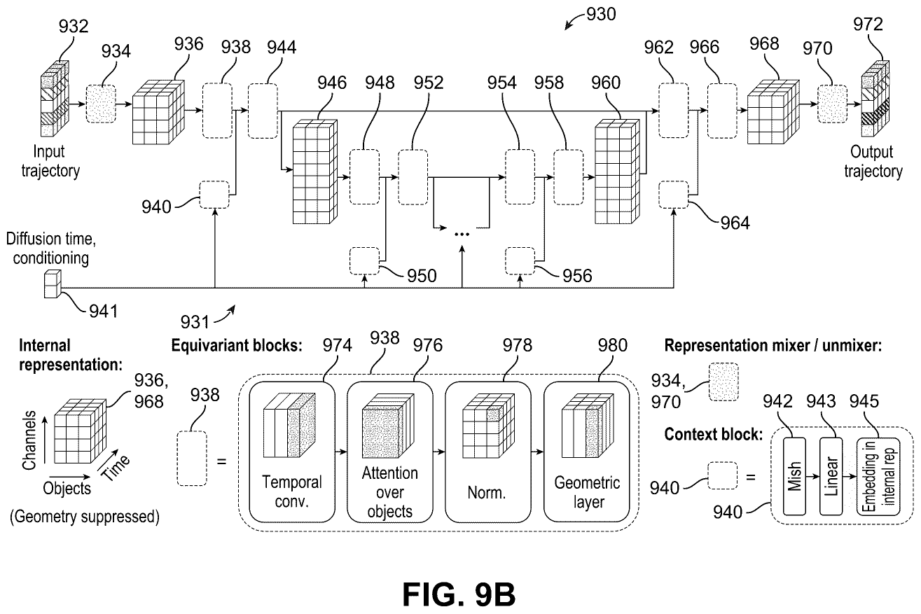

At block 824, the process 820 includes, for each step, constructing all scalars (or inner products) from the intermediate vectors to generate derived scalars. At block 826, the process 820 includes concatenating the input scalars with the derived scalars to generate concatenated scalars. At block 828, the process 820 includes linearly transforming the concatenated scalars to a set of scalars. At block 830, the process 820 includes feeding the set of scalars through a U-Net architecture (e.g., see the U-Net architecture 900 of FIG. 9A or the alternate U-Net architecture 931 of FIG. 9B) of a diffuser architecture to generate U-Net output scalars. At block 832, the process 820 includes setting the U-Net output scalars to be a first num_scalars components of the U-Net output scalars. At block 834, the process 820 includes processing remaining components of the U-Net output scalars into two linear matrices that act on the input vectors.

In some examples, the processes described herein (e.g., processes 800/820 and/or any other process described herein) may be performed by a computing device, apparatus, or system. In some examples, the processes 800/820 can be performed by the computing system 1300 of FIG. 13. The computing device, apparatus, or system can include any suitable device, such as a mobile device (e.g., a mobile phone), a desktop computing device, a tablet computing device, a wearable device, a server computer, an autonomous vehicle or computing device of an autonomous vehicle, a robotic device, a laptop computer, a smart television, a camera, and/or any other computing device with the resource capabilities to perform the processes described herein, including the processes 800/820 and/or any other process described herein. In some cases, the computing device or apparatus may include various components, such as one or more input devices, one or more output devices, one or more processors, one or more microprocessors, one or more microcomputers, one or more cameras, one or more sensors, and/or other component(s) that are configured to carry out the steps of processes described herein. In some examples, the computing device may include a display, a network interface configured to communicate and/or receive the data, any combination thereof, and/or other component(s). The network interface may be configured to communicate and/or receive Internet Protocol (IP) based data or other type of data.

The components of the computing device can be implemented in circuitry. For example, the components can include and/or can be implemented using electronic circuits or other electronic hardware, which can include one or more programmable electronic circuits (e.g., microprocessors, graphics processing units (GPUs), digital signal processors (DSPs), central processing units (CPUs), and/or other suitable electronic circuits), and/or can include and/or be implemented using computer software, firmware, or any combination thereof, to perform the various operations described herein.

The processes 800/820 are illustrated as logical flow diagrams, the operation of which represents a sequence of operations that can be implemented in hardware, computer instructions, or a combination thereof. In the context of computer instructions, the operations represent computer-executable instructions stored on one or more computer-readable storage media that, when executed by one or more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the processes.

Additionally, the processes 800/820 and/or any other process described herein may be performed under the control of one or more computer systems configured with executable instructions and may be implemented as code (e.g., executable instructions, one or more computer programs, or one or more applications) executing collectively on one or more processors, by hardware, or combinations thereof. As noted above, the code may be stored on a computer-readable or machine-readable storage medium, for example, in the form of a computer program including a plurality of instructions executable by one or more processors. The computer-readable or machine-readable storage medium may be non-transitory.

Further details regarding the transformation of the data into internal representations are discussed next. First the input trajectory is transformed into the internal representation in the following way by the training preparation engine 704. Each input quaternion q_{toc}∈ [symbol] ⁴ is transformed into two SO(3) vectors by mapping it to the corresponding SO(3) element in the matrix representation and keeping the first two column vectors. Then, for each object o∈{1, . . . , n}, for each trajectory step t∈{1, . . . , T}, and each channel c={1, . . , n_{c}}, the input is defined in the internal representation as w_{toc}∈ [symbol] ⁴ as follows:

$${w}_{toc} = ( \begin{matrix}{\sum }_{{c}^{′}} {W}_{{icc}^{′}}^{1} {s}_{{toc}^{′}} \\ {\sum }_{{c}^{′}} {W}_{{icc}^{′}}^{2} {v}_{{toc}^{′}}\end{matrix} ) + ( \begin{matrix}{\sum }_{{c}^{′}} {W}_{{icc}^{′}}^{3} {s}_{t ∅ {c}^{′}} \\ {\sum }_{{c}^{′}} {W}_{{icc}^{′}}^{3} {v}_{t ∅ {c}^{′}}\end{matrix} ) . \qquad ( 5 )$$

Here v_{toc′} includes the vectors derived from the quaternions. The matrices W^{1,2,3,4} are learnable and n×n_{c}×nₛ-dimensional, n×n_{c}×nₛ-dimensional, n×n_{c}×nₛ-dimensional, and n×n_{c}×nₛ-dimensional, respectively. Here nₛ is the number of scalar quantities associated with each object in the trajectory, nᵥ is the number of vector quantities associated with each object, n^{∅}ₛ is the number of global scalar quantities, and n^{∅}ᵥ is the number of global vectorial quantities. The number of channels n_{c} is a hyperparameter. It should be chosen as n_{c}≥max(n_{c}+n^{∅}_{c}, nᵥ+n^{∅}ᵥ), otherwise the network will not in general be able to model arbitrary denoising functions.

A second step involves processing internal representations equivariantly in the geometric EGNN or the equivariant network 706. The system then process the data with a SO(3)× [symbol] ×sₙ-equivariant denoising network. It is constructed out of three alternating types of layers. Each type acts on the representation dimension of one of the three symmetry groups, while leaving the other two invariant. One set of layers can include temporal layers. Temporal layers include one-dimensional convolutions along the trajectory-step dimension. They can be organized in a U-Net architecture 900 as shown in FIG. 9A. There is no mixing between features associated with different objects, nor between the four geometric features of the internal SO(3) representation.

The temporal layers can be time-translation-equivariant convolutions along the temporal direction (e.g., along trajectory steps). FIG. 9A illustrates the U-Net architecture 900 can have various layers 902. The U-Net architecture 900 is illustrated with repeated blocks 904 (e.g., six repeatable blocks or residual blocks). Each block includes two temporal convolutions, each followed by a group normalization (GN), and a final mish nonlinearity. Timestep embeddings are produced by a single fully-connected layer 906 and added to the activations of the first temporal confusion within each block. In some cases, a diffuser (e.g., the equivariant diffuser 714) can have the U-Net architecture 900 with residual blocks including temporal convolutions, a block for group normalization, and a block for mish nonlinearities. Mish is a self-regularized non-monotonic activation function which can play a role in performance and training dynamics and neural networks. The U-Net architecture 900 can be geometric and can treat states-actions trajectories as images. In some aspects, the network uses linear combinations of scalar quantities to preserve equivariances. As shown, the repeated blocks 904 can include a one-dimensional convolutional layer 908 that receives “x” data and a single fully-connected layer 906 that receives “t” data, the output of which is combined using a combiner 910 to generate a group normalization (GN) and mish data. The GN and mish data is processed by a one-dimensional convolutional layer 912 to generate additional GN and mish data. The additional GN and mish data is added to the “x” data using combiner 914 to generate an output. The GN and mish data do not mix between different objects, nor between the four geometric features of each internal representation.

FIG. 9B illustrates an alternate U-Net architecture 931.

Another set of layers includes permutation layers. Permutation-equivariant self-attention layers are used over the object dimension. These do not mix between different time steps, nor between the four geometric features of each internal representation. Permutation layers allow the features with different objects to interact. There is no mixing between features associated with different time steps, nor between the four geometric features of the internal SO(3) representation. The permutation layers can be implemented through a self-attention mechanism.

Given inputs w_{toc}, the system can compute:

$${K}_{toc} = {\sum }_{{c}^{′}} {W}_{{cc}^{′}}^{K} {w}_{toc} \qquad ( 6 )$$

$${Q}_{toc} = {\sum }_{{c}^{′}} {W}_{{cc}^{′}}^{Q} {w}_{toc}$$

$${V}_{toc} = {\sum }_{{c}^{′}} {W}_{{cc}^{′}}^{V} {w}_{toc}$$

$${w}_{i}^{′} ∝ {\sum }_{{o}^{′}} {softmax}_{{o}^{′}} ( {Q}_{toc} \cdot {K}_{{to}^{′} c} ) {V}_{{to}^{′} c}$$

with learnable weight matrices W^{K,V,Q}. The computation according to Equation (6) is SO(3)-equivariant, as the scalar product in the attention weights computes invariant SO(3) norms.

Another set of layers include geometric layers in which a SO(3)-equivariant interaction can be processed between the different geometric features within each internal representation. These do not mix between different time steps, nor between different objects. Geometric layers enable mixing between the scalar and vector quantities that are combined in the internal representation, but do not mix between objects or trajectory steps. As performed by the training preparation engine 704, the system first separates the inputs into SO(3) scalar and vector components, w_{toc}=(s_{toc}, v_{toc})^{T}. Then the engine constructs all scalars that can be constructed for each object and time step:

$${S}_{to} = {\{ {s}_{toc} \}}_{c} ⋃ {\{ {v}_{toc} \cdot {v}_{{toc}^{′}} \}}_{c , {c}^{′}} . \qquad ( 7 )$$

These are then used as inputs to two multilayer perceptrons (MLPs) ϕ and ψ, and finally output scalars and vectors are produced:

$${s}_{toc}^{′} = {ϕ ( {S}_{to} )}_{c} , \qquad ( 8 )$$

$${v}_{toc}^{′} = {\sum }_{{c}^{′}} {ϕ ( {S}_{to} )}_{{cc}^{′}} {v}_{{toc}^{′}} , \qquad ( 9 )$$

The next step involves mapping to output representations. The equivariant network outputs internal representations w_{toc}. The system then transforms them back to the data representations with linear maps, in analogy to equation (5) above. In this way, the system outputs one scalar ϵ\hat{ } is ₜ for each input scalar, one vector ϵ\hat{ }ⁱ_{v t} for each input vector. In addition, for each input quaternion, it outputs one scalar h^{′i}ₜ and one vector hⁱₜ.

Finally, the quaternionic output is computed as ϵ\hat{ }ⁱ_{q t}=(h^{′i}ₜ, hⁱₜ)ºqⁱₜ, where º denotes the Hamilton product between quaternions and (h^{′i}ₜ, hⁱₜ) is the quaternion that includes the real part h^{′i}ₜ and complex parts hⁱₜ.

The trained model of the equivariant diffuser 714 shown in FIG. 7 is equivariant with respect to SO(3)× [symbol] ×Sₙ. It can perform to provide output of the model even it if is only trained on some movement for example of a robot, where it can leverage the symmetries of physics to also perform or provide trajectories for other associated movements that are possible for the robot. Equivariance with respect to time translations follows from the choice of one-dimensional convolutions along the temporal directions as shown by the single fully-connected layer 906 in FIG. 9A. Equivariance with respect to permutations follows from the permutation equivariance of the self-attention blocks. SO(3) equivariance is similarly baked into the message-passing operations. It is easy to show that the construction of quaternions from scalars and vectors is also an SO(3)-equivariant operation.

In addition, the network is also equivariant under sign flips of any input quaternion. Such a property is important when parameterizing object orientations with quaternions, as each object orientation R can be described by two quaternions q_{R} and −q_{R}.

The denoising model is trained on the simplified loss as follows:

$$ℒ = {𝔼}_{r , i , ϵ} [ {‖ ϵ - f ( τ + ϵ ; i ) ‖}^{2} ] . \qquad ( 10 )$$

Here τ is a trajectory from the training data, i˜Uniform(0, N) is the diffusion time step, and ϵ is Gaussian noise with variance depending on i following a noise schedule.

As shown in FIG. 7, unconditional sampling or handling unconditional trajectories 708 can occur. To sample from the unconditional trajectory density p(τ), one first samples a trajectory from uncorrelated Gaussian noise, τN˜N (0, 1). The data is then iteratively denoised as

$${τ}_{i - 1} ∼ 𝒩 ( \cdot \vert {μ}_{i} , {σ}_{i}^{2} ) , \qquad ( 11 )$$

$${μ}_{i} = \frac{1}{\sqrt{{α}_{i}}} ( {τ}_{i} - \frac{{β}_{i}}{\sqrt{1 - {\overline{α}}_{i}}} f ( {τ}_{i} ; i ) ) , \qquad ( 12 )$$

where αᵢ, α⁻ᵢ, βᵢ, and σᵢ depend on the noise schedule.

As shown in FIG. 7, output from the equivariant classifier 710 can be provided to a test time rewards engine 712 that can implement goal conditioning as equivariant image inpairing and provide specific new tasks via rewards. To maximize the reward of any given task, the system follows some procedures. For each task, the system trains a regression model J(τ) to estimate the cumulative reward achieved by a trajectory τ. The system then samples from the equivariant diffuser model with classifier guidance from J(τ): rather than with equation (12), the system can denoise with mean:

$${\overline{μ}}_{i} = {μ}_{i} + {∇}_{τ} J ( {μ}_{i} ) . \qquad ( 13 )$$

The system can process conditional trajectories 716 as well. The equivariant diffuser 714 allows the system to sample conditional constraints on states or actions. By conditioning on the initial state and maximizing the expected cumulative reward implemented by the test time rewards engine 712 as described above, the system can solve reinforcement learning problems. Alternatively, by conditioning on the initial and final state, the system can solve goal-conditioned RL problems even without training a reward predictor.

Conditional sampling can be performed similarly as the unconditional sampling, except that, for conditional sampling, the system can fix the desired states and actions in order to condition on to the conditioning values after every de-noising step.

FIG. 9B illustrates an example of a more detailed framework for an equivariant diffusion model 930. The architecture of a SE(3)×Z×Sn-equivariant denoising network is shown in FIG. 9B. Input trajectories 932, which include features in different representations of the symmetry group, can be transformed into a single internal representation via a representation mixer 934. The data is then processed with equivariant blocks 938, 944, 948, 952, 954, 958, 962, 966. In some aspects, the equivariant blocks 938, 944, 948, 952, 954, 958, 962, 966 can include convolutional layers along the time dimension, attention over objects, normalization layers, and geometric layers, which mix scalar and vector components of the internal representations. The equivariant blocks can be combined into an alternate U-Net architecture 931. Conditioning information and diffusion time 941 can be fed into the pipeline from context blocks 940 at each level of the alternate U-Net architecture 931 via the context blocks 940. In some cases, context blocks also include context blocks 950, 956 and 964. A second internal representation of the output 968 can be separated into the original data representation. For simplicity, FIG. 9B does not include some details, including residual connections, downsampling, and upsampling layers.

The equivariant diffusion model 930 can be characterized as a SE(3)× [symbol] × [symbol] ₙ-invariant diffusion model. The equivariant diffusion model 930 can a base density that is invariant with respect to a symmetry group and a denoising model that is equivariant with respect to the symmetry group. Such a diffusion model then has a SE(3)× [symbol] × [symbol] ₙ-invariant probability distribution.

As a base density, the approach in some aspects can use a multi-dimensional standard normal distribution, which has the required invariance properties. The novel equivariant architecture for the denoising model ƒ can be implemented as a neural network and can map noisy input trajectories τ and a diffusion time step i to an estimate \hat{ϵ} of the noise vector that generated the input. In some aspects, the equivariant diffusion model 930 can achieve such a result in at least three steps. For example, in a first step, input trajectories 932 including various representations can be transformed into an internal representation of the symmetry group. In a second step, in the representation, the data can be processed with an equivariant network. In a third step, the outputs can be transformed from the internal representation into the original representations present in the trajectory. FIG. 9B illustrates the architecture of the equivariant diffusion model 930.

In some cases, according to the first step, the representation mixer 934 can receive the input trajectories 932. The noisy trajectory inputs may include features in different representations of the symmetry group. While it is possible to mirror these input representations for the hidden states of the neural network, the design of equivariant architectures is substantially simplified if all inputs and outputs transform under a single representation. The approach described herein may thus decouple the data representation from the representation used internally for the computation.

A single internal representation 936 of the data is introduced. The single internal representation 936, for each trajectory time step t∈{1, . . . , H}, for each object i∈{1, . . . , n}, for each channel c∈{1, . . . , n_{c}}, can includes one SO(3) scalar s_{toc} and one SO(3) vector v_{toc}. In some aspects, the dimensions of the internal representation 936 can be channels, objects, and time, as shown in FIG. 9B. In some cases, one scalar can be paired with one vector. In other cases, such as for systems in which scalar or vectorial quantities play a larger role, the approach may be to use multiple copies of either representation. The system can write w_{toc}=(s_{toc}, v_{toc})∈ [symbol] ⁴. Under spatial rotations g∈SO(3), these features thus can transform as the direct sum of the scalar and the vector representation ρ₀⊕ ρ₁:

$${w}_{toc} = ( \begin{matrix}{s}_{toc} \\ {v}_{toc}\end{matrix} ) \to {w}_{toc}^{′} = ( \begin{matrix}{ρ}_{0} ( g ) {s}_{toc} \\ {ρ}_{1} ( g ) {v}_{toc}\end{matrix} ) . \qquad ( 14 )$$

These internal features can transform in the regular representation under time shift and in the standard representation under permutations as w_{toc}→w_{to′c}=Σₒ [symbol] _{o′o}w_{toc}. There are thus no global (not object-specific) properties in our internal representations. Examples are described below of embedding robotic properties into the above-described representation.

Examples of transforming input representations into internal representations will now be described. For example, a first layer in the neural network can transform the input trajectories 932 (e.g., including features in different representations of the symmetry group SE(3)× [symbol] × [symbol] ₙ) into the single internal representation 936. The system can pair up SO(3) scalars and SO(3) vectors into ρ₀⊕ρ₁ features. The system can also remove global features which are those unassigned to one of the n objects in the scene by including them in the representation of each of the n objects.

In some examples, for each object o∈{1, . . . , n}, each trajectory step t∈{1, . . . , T}, and each channel c={1, . . . , nₙ}, the system can define the input in the internal representation as w_{toc}∈ [symbol] ⁴ as follows:

$${w}_{toc} = ( \begin{matrix}{\sum }_{{c}^{′}} {W}_{{occ}^{′}}^{1} {s}_{{toc}^{′}} \\ {\sum }_{{c}^{′}} {W}_{{occ}^{′}}^{2} {s}_{{toc}^{′}}\end{matrix} ) + ( \begin{matrix}{\sum }_{{c}^{′}} {W}_{{occ}^{′}}^{3} {s}_{t ∅ {c}^{′}} \\ {\sum }_{{c}^{′}} {W}_{{occ}^{′}}^{4} {s}_{vt ∅ {c}^{′}}\end{matrix} ) . \qquad ( 15 )$$

The matrices W^{1,2,3,4} are learnable and of dimension n×n_{c}×nₛ^{object}, n×n_{c}×nᵥ^{object}, n×n_{c}×nₛ^{global} or n×n_{c}×nᵥ^{global}, respectively. Here, nₛ^{object} is the number of SO(3) scalar quantities associated with each object in the trajectory, nᵥ^{object} is the number of SO(3) vector quantities associated with each object, nₛ^{global} is the number of scalar quantities associated with the robot or global properties of the system, and nᵥ^{global} is the number of vectors of that nature. The number of input channels n_{c} is a hyperparameter. The system can initialize the matrices Wⁱ such that Eq. (15) corresponds to a concatenation of all object-specific and global features along the channel axis at the beginning of training, but leave them learnable. Note that equation (15) is similar to equation (5) above.

In some cases, according to the second step, the system can apply SE(3)× [symbol] × [symbol] ₙ-equivariant U-net. The system can then process the data with a SE(3)× [symbol] × [symbol] ₙ-equivariant denoising network or equivariant blocks 938. Components of the denoising network include three alternating types of layers. Each type of layer can act on the representation dimension of one of the three symmetry groups, while leaving the other two invariant. In some aspects, the equivariant blocks 938 include temporal layers 974. The temporal layers 974 can include time-translation-equivariant convolutions along the temporal direction (e.g., along trajectory steps), organized in an alternate U-Net architecture 931. The temporal layers 974 may not mix between different objects, nor between the four geometric features of each internal representation. The equivariant blocks 938 may also include object layers. For example, permutation layers 976 can be referred to as permutation-equivariant self-attention layers over the object dimension. These layers may not mix between different time steps, nor between the four geometric features of each internal representation. The equivariant blocks 938 may also include a normalization layer 978. The equivariant blocks 938 can further include geometric layers 980, such as a SO(3)-equivariant interaction between the scalar and vector features within each internal representation. The geometric layers 980 may not mix between different time steps, nor between different objects.

In some aspects, the system can use residual/skip connections, a new type of normalization layer 978 that does not break equivariance. The system can also include context blocks 940 that process conditioning information and embed it in the internal representation. To perform these functions, the context blocks 940 can include a mish module 942, a linear module 943, and an embedding module 945. The mish module 942 relates to a self-regularized non-monotonic activation function which can play a role in performance and training dynamics and neural networks.

The above-described layers can be combined into an equivariant block including one instance of each layer, and the equivariant blocks are arranged in the alternate U-Net architecture 931, as shown in FIG. 9B. Between the levels of the alternate U-Net architecture 931, the system can downsample (or upsample) along the trajectory time dimension (e.g., by factors of two), increasing (or decreasing) the number of channels correspondingly.

The temporal layers 974 include one-dimensional convolutions along the trajectory time dimension. To preserve SO(3) equivariance, these convolutions may not add any bias. In some cases, there is no mixing between features associated with different objects, nor between the four geometric features of the internal SO(3) representation.

The permutation layers 976 allow the features with different objects to interact through the equivariant self-attention layer. In some cases, there is no mixing between features associated with different time steps, nor between the four geometric features of the internal SO(3) representation.

Given inputs w_{toc}, the permutation layer computes:

$${K}_{toc} = {\sum }_{{c}^{′}} {W}_{c {c}^{′}}^{K} {w}_{toc} , {Q}_{toc} = {\sum }_{{c}^{′}} {W}_{c {c}^{′}}^{Q} {w}_{toc} , {V}_{toc} = {\sum }_{{c}^{′}} {W}_{{{cc}^{′}}^{W} toc}^{V} , {w}_{t}^{i} \cdot \qquad ( 16 )$$

$$∝ {\sum }_{{o}^{′}} {softmax}_{{o}^{′}} ( {Q}_{toc} \cdot {K}_{{to}^{′} c} ) {V}_{{to}^{′} c}$$

with learnable weight matrices W_{K,V,Q}. The output of equation (16) is SO(3)-equivariant, as the scalar product in the attention weights computes invariant SO(3) norms.

The geometric layers 980 are the third layer type. These layers enable mixing between the scalar and vector quantities that are combined in the internal representation, but do not mix between different objects or across the time dimension. The system constructs an expressive equivariant map between scalar and vector inputs and outputs: The system first separates the inputs into SO(3) scalar and vector components, w_{toc}=(s_{toc}, v_{toc})^{T} then constructs a complete set of SO(3) invariants by combining the scalars and pairwise inner products between the vectors, Sₜₒ=(s_{toc})_{c}∪{v_{toc}·v_{toc′}}_{c,c′}. These are then used as inputs to two MLPs, ∅ and ψ. The system can then produce output scalars and vectors as follows:

$${w}_{toc}^{′} ( {∅ ( {S}_{to} )}_{c} , {\sum }_{{c}^{′}} {∅ ( {S}_{to} )}_{{cc}^{′}} {v}_{{toc}^{′}} ) . \qquad ( 17 )$$

The system can approximate any equivariant map between SO(3) scalars and vectors under mild assumptions. In its original form, however, it can become prohibitively expensive, as the number of SO(3) invariants Sₜₒ scales quadratically with the number of channels. The system can therefore first linearly transform the input vectors into a smaller number of vectors, apply the transformation, and increase the number of channels again with another linear transformation.

The equivariant blocks 938 can also be included as equivariant blocks 944, 948, 952, 954, 958, 962, 966. The output of, for example, equivariant block 944 is a second internal representation 946 of the data. The output of equivariant block 958 is a third internal representation of data 960, which is input to another equivariant block 962. The output of equivariant block 966 is a second internal representation of the output 968.

A next step can include the representation unmixer 970 processing the second internal representation of the output 968, which can be internal representations w_{toc}. The system can then transform the internal representations w_{toc} back to the data representations with linear maps. Global properties, for instance robotic degrees of freedom, are aggregated from the object-specific internal representations by taking the mean, minimum, and maximum across the objects. These three aggregates are then concatenated along the channel dimension. The output trajectory 972 is shown as the output of the equivariant diffusion model 930. It can be beneficial to apply an additional geometric layer to these aggregated global features before separating them into the original representations.

In some aspects, the diffusion model of FIG. 9B can be trained on offline trajectory data {τ}, which does not need to include reward information. The system can use the simplified diffusion loss, [symbol] = [symbol] _{τ,i,ϵ}[∥ϵ−ƒ(τ+ϵ; i)∥²]. Here, τ is a trajectory from the training data, i˜Uniform(0, N) is the diffusion time step, and ϵ is Gaussian noise with variance depending on ᵢ following a noise schedule.

A diffusion model trained on offline trajectory data jointly learns a world model and a policy. The system can use it to solve planning problems (e.g., choosing a sequence of actions to maximize the expected rewards).

In some aspects, the system can perform planning with equivariant diffusion, such as using various features of diffusion models. For example, the system can utilize the ability to sample from diffusion models by drawing noisy data from the base distribution and iteratively denoising the diffusion models with the learned network, which can provide the system with trajectories similar to those in the training set. For such sampled trajectories to be useful for planning, the sampled trajectories can begin in the current state of the environment. For example, the sampling process can be conditioned such that the initial state of the generated trajectories matches the current state. The system can guide the sampling process towards solving concrete tasks specified at test time, which may include training a regression model to map trajectories to the return under a given task. The sampling iterations can then be biased towards trajectories with a high return. Combining these pieces, the system can use conditioned sampling guided by a reward model in a closed sampling loop.

The system can also utilize the concept of symmetry breaking. By construction, the equivariant diffusion model learns a SE(3)× [symbol] × [symbol] ₙ-invariant density over trajectories. Unconditional samples will reflect the symmetry property: it will be equally likely to sample a trajectory and its rotated or permuted counterpart.

The following table illustrates performance on navigation tasks and on block stacking problems with a Kuka robot.

| | | | | | EqD | EqD | EqD |
|---|---|---|---|---|---|---|---|
| | | | | | (SE(3) × | ( [symbol] × | (SE(3) × |
| Environment | BCQ | CQL | Diffuser | Diffuser | [symbol] ) | [symbol] ₙ) | [symbol] × [symbol] ₙ) |
| Navigation | — | — | — | | | | |
| Unconditional | 0.0 | 24.4 | 58.7 ± 2.5 | 61.3 ± 2.7 | 59.0 ± 2.7 | 78.7 ± 2.2 | 62.0 ± 2.1 |
| Conditional | 0.0 | 0.0 | 45.6 ± 3.1 | 52.3 ± 3.5 | 14.7 ± 2.0 | | |
| Rearrangement | 0.0 | 0.0 | 58.9 ± 3.4 | 54.0 ± 3.5 | 17.0 ± 2.5 | | |
| Average | 0.0 | 8.1 | 54.4 | 55.9 | 30.2 | | |

Concrete tasks may break the invariance discussed above. For instance, invariance can be broken by requiring that a robot or object is brought into a particular location. The equivariant diffuser approach allows the system to elegantly break the symmetry at test time for concrete tasks. Such a soft symmetry breaking can happen through conditioning, for instance by specifying the initial or final state of the sampled trajectories, or through a non-invariant reward model used for guidance during sampling.

Each of the geometric quantities can be treated separately towards building equivariant maps under a prescribed group G (e.g., G=SE(3)).

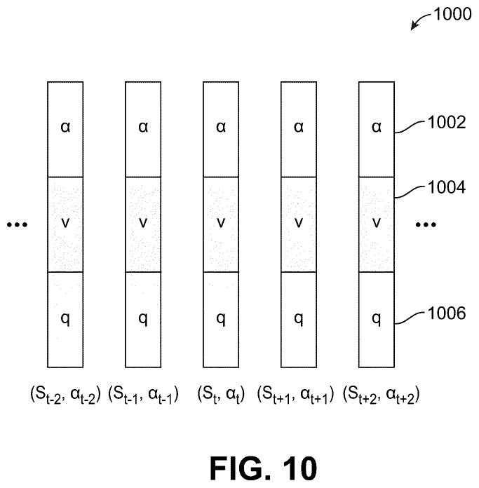

FIG. 10 illustrates the various data 1000 which can include scalars which can be associated with angles and torques 1002. Torques for the purposes herein can correspond to the angular force applied between the joint coordinates and are represented in radians. Consequently, as a geometric quantity, it is invariant to any action of g∈SE(3) and can be treated as a scalar quantity.

Other data 1004 can be presented as vectors and can be associated with a position: In the observation space of an example robot stacking environment, the task might include four cubes the centers of which are given as positions in three-dimensional space. Positions vectors transform in the standard representation under the action of g∈SE(3).

Additional data 1006 can include quaternions. By themselves, quaternions are tricky to reason using geometric types. A method can be used to convert quaternions to 3×3 rotation matrices. The matrix itself can be viewed as a flattened 9-dimensional vector that carries with it three copies of the standard representation. Another dimension of each cube can correspond to a binary variable of whether the cube is attached to an arm of a robot. From a geometric perspective, a scalar quantity can be used that is invariant to the action of SE(3) and can relate to an attachment state.

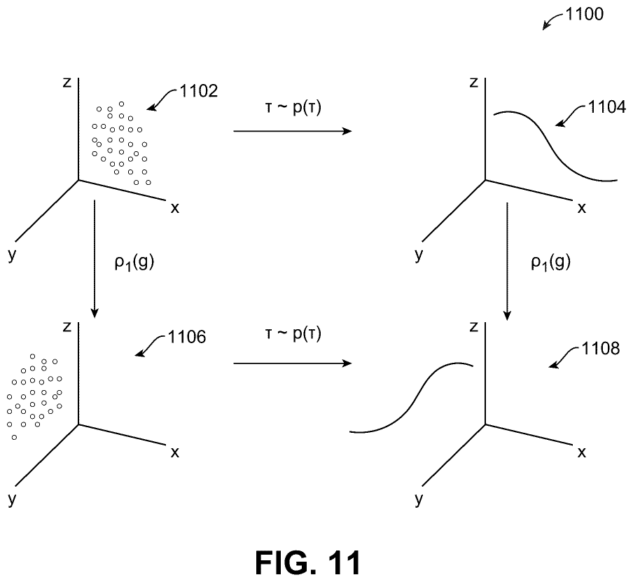

FIG. 11 is a diagram 1100 illustrating an example of equivariant trajectory generation, according to aspects of the disclosure. The first set of noisy data 1102 in a Cartesian coordinate system can be denoised as shown with τ˜p(τ) and the resulting denoised trajectory 1104 in the same cartesian coordinate system. The first set of noisy data 1102 can also be shown to have some symmetry transformation via p₁(g) into transformed data 1106 with a new symmetric position. Then, the transformed data 1106 can be also denoised via τ˜p(τ) to generate the output 1108 in the same Cartesian coordinate system.

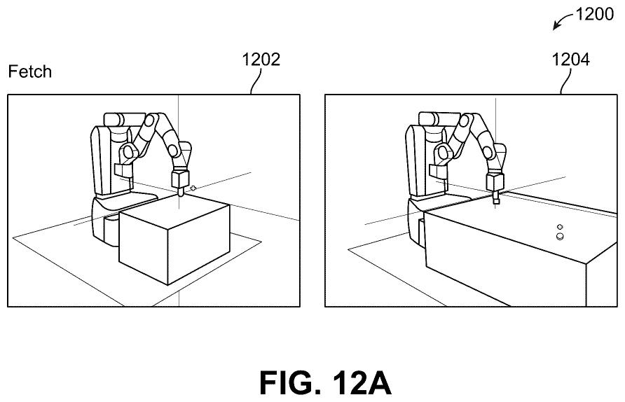

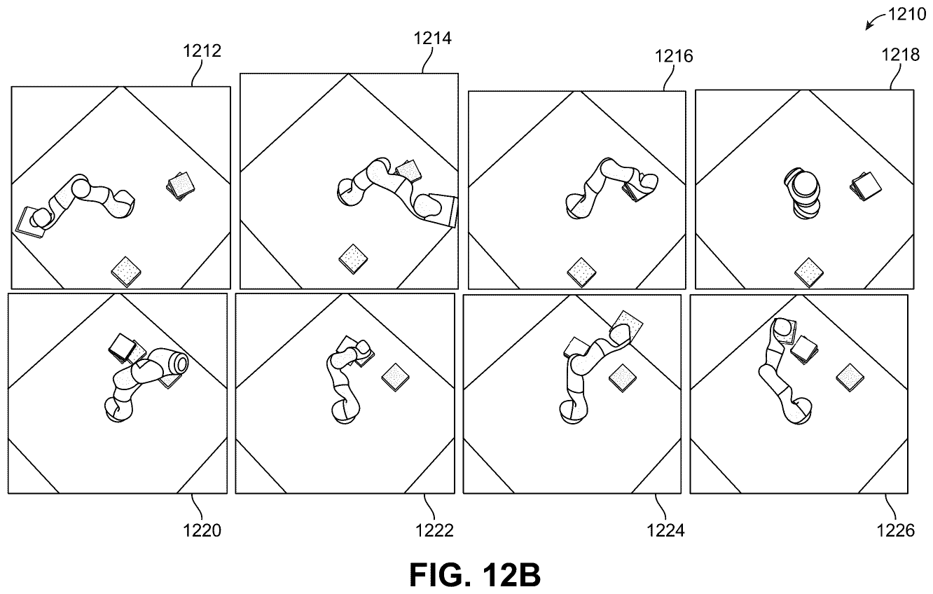

FIG. 12A is a diagram 1200 illustrating an example use related to robotics, according to aspects of the disclosure. For example, a fetch operation can be performed a robot with a first state 1202 and a second state 1204 in which the robot is performing an action. Robotic learning practitioners can use the concepts disclosed herein to construct plans that are data efficient in which symmetries can help. In some aspects, text time task specification can be used to divide the symmetry group or break equivariance which gives some flexibility to the modelers as well. The architecture provides a general recipe for many geometric data types which enable further use in different environments which can include different robot or other types of environments.

FIG. 12B is a diagram 1210 illustrating an example use related to robotics showing trajectories generated by the equivariant diffuser model, according to aspects of the disclosure. For example, a robot can perform different tasks or have different states 1212, 1214, 1216, 1218, 1220, 1222, 1224, 1226 as part of a trajectory or plan to move objects from one place to another or to perform any kind of task.

FIG. 13 is a diagram illustrating an example of a system for implementing certain aspects of the present technology. In particular, FIG. 13 illustrates an example of computing system 1300, which can be for example any computing device making up internal computing system, a remote computing system, a camera, or any component thereof in which the components of the system are in communication with each other using connection 1305. Connection 1305 can be a physical connection using a bus, or a direct connection into processor 1310, such as in a chipset architecture. Connection 1305 can also be a virtual connection, networked connection, or logical connection.

In some aspects, computing system 1300 is a distributed system in which the functions described in this disclosure can be distributed within a datacenter, multiple data centers, a peer network, etc. In some aspects, one or more of the described system components represents many such components each performing some or all of the function for which the component is described. In some aspects, the components can be physical or virtual devices.

Example computing system 1300 includes at least one processing unit (CPU or processor) which can be characterizes as a processor 1310 and connection 1305 that couples various system components including system memory 1315, such as read-only memory (ROM) memory 1320 and random-access memory (RAM) memory 1325 to processor 1310. Computing system 1300 can include a cache 1311 of high-speed memory connected directly with, in close proximity to, or integrated as part of processor 1310.

Processor 1310 can include any general-purpose processor and a hardware service or software service, such as services 1332, 1334, and 1336 stored in storage device 1330, configured to control processor 1310 as well as a special-purpose processor where software instructions are incorporated into the actual processor design. Processor 1310 may essentially be a completely self-contained computing system, containing multiple cores or processors, a bus, memory controller, cache, etc. A multi-core processor may be symmetric or asymmetric.

To enable user interaction, computing system 1300 includes an input device 1345, which can represent any number of input mechanisms, such as a microphone for speech, a touch-sensitive screen for gesture or graphical input, keyboard, mouse, motion input, speech, etc. Computing system 1300 can also include output device 1335, which can be one or more of a number of output mechanisms. In some instances, multimodal systems can enable a user to provide multiple types of input/output to communicate with computing system 1300. Computing system 1300 can include communications interface 1340, which can generally govern and manage the user input and system output.

The communication interface may perform or facilitate receipt and/or transmission wired or wireless communications using wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer. 802.11 Wi-Fi wireless signal transfer, WLAN signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/long term evolution (LTE) cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

The communications interface 1340 may also include one or more GNSS receivers or transceivers that are used to determine a location of the computing system 1300 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1330 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a Blu-ray disc (BDD) optical disc, a holographic optical disk, another optical medium, a secure digital (SD) card, a micro secure digital (microSD) card, a Memory Stick® card, a smartcard chip, a Europay, Mastercard and Visa (EMV) chip, a subscriber identity module (SIM) card, a mini/micro/nano/pico SIM card, another integrated circuit (IC) chip/card, RAM, static RAM (SRAM), dynamic RAM (DRAM), ROM, programmable read-only memory (PROM), erasable programmable read-only memory (EPROM), electrically erasable programmable read-only memory (EEPROM), flash EPROM (FLASHEPROM), cache memory (L1/L2/L3/L4/L5/L#), resistive random-access memory (RRAM/ReRAM), phase change memory (PCM), spin transfer torque RAM (STT-RAM), another memory chip or cartridge, and/or a combination thereof.

The storage device 1330 can include software services, servers, services, etc., that when the code that defines such software is executed by the processor 1310, it causes the system to perform a function. In some aspects, a hardware service that performs a particular function can include the software component stored in a computer-readable medium in connection with the necessary hardware components, such as processor 1310, connection 1305, output device 1335, etc., to carry out the function. The term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections.

The term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, an engine, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

In some aspects, the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Specific details are provided in the description above to provide a thorough understanding of the aspects and examples provided herein. However, it will be understood by one of ordinary skill in the art that the aspects may be practiced without these specific details. For clarity of explanation, in some instances the present technology may be presented as including individual functional blocks including devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the aspects in unnecessary detail. In other instances, well-known circuits, processes, algorithms, structures, and techniques may be shown without unnecessary detail in order to avoid obscuring the aspects.

Individual aspects may be described above as a process or method which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

Processes and methods according to the above-described examples can be implemented using computer-executable instructions that are stored or otherwise available from computer-readable media. Such instructions can include, for example, instructions and data which cause or otherwise configure a general-purpose computer, special purpose computer, or a processing device to perform a certain function or group of functions. Portions of computer resources used can be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

Devices implementing processes and methods according to these disclosures can include hardware, software, firmware, middleware, microcode, hardware description languages, or any combination thereof, and can take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Typical examples of form factors include laptops, smart phones, mobile phones, tablet devices or other small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are example means for providing the functions described in the disclosure.

In the foregoing description, aspects of the application are described with reference to specific aspects thereof, but those skilled in the art will recognize that the application is not limited thereto. Thus, while illustrative aspects of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, aspects can be utilized in any number of environments and applications beyond those described herein without departing from the broader spirit and scope of the specification. The specification and drawings are, accordingly, to be regarded as illustrative rather than restrictive. For the purposes of illustration, methods were described in a particular order. It should be appreciated that in alternate aspects, the methods may be performed in a different order than that described.

One of ordinary skill will appreciate that the less than (“<”) and greater than (“>”) symbols or terminology used herein can be replaced with less than or equal to (“≤”) and greater than or equal to (“≥”) symbols, respectively, without departing from the scope of this description.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Claim language or other language reciting “at least one processor configured to,” “at least one processor being configured to,” “a processor configured to,” or the like indicates that one processor or multiple processors (in any combination) can perform the associated operation(s). For example, claim language reciting “at least one processor configured to: X, Y, and Z” means a single processor can be used to perform operations X. Y, and Z; or that multiple processors are each tasked with a certain subset of operations X, Y, and Z such that together the multiple processors perform X. Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

The various illustrative logical blocks, modules, engines, circuits, and algorithm steps described in connection with the examples disclosed herein may be implemented as electronic hardware, computer software, firmware, or combinations thereof. To clearly illustrate this interchangeability of hardware and software, various illustrative components, blocks, modules, engines, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules, engines, or components may be implemented together in an integrated logic device or separately as discrete but interoperable logic devices. If implemented in software, then the techniques may be realized at least in part by a computer-readable data storage medium including program code including instructions that, when executed, performs one or more of the methods, algorithms, and/or operations described above. The computer-readable data storage medium may form part of a computer program product, which may include packaging materials. The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

Illustrative aspects of the disclosure include:

Aspect 1. A processor-implemented method of modeling tasks using a geometric structure, the processor-implemented method comprising: receiving, via a training preparation engine, a training dataset comprising state-action pairs; separating, via the training preparation engine, the state-action pairs from the training dataset into geometric data types; converting. via the training preparation engine, the geometric data types into internal representations; processing, via an equivariant denoising network, the internal representations to generate output data; and transforming the output data to a data representation.

Aspect 2. The processor-implemented method of Aspect 1, wherein the equivariant denoising network includes alternating types of layers.

Aspect 3. The processor-implemented method of Aspect 2, wherein the alternating types of layers comprise temporal layers, permutation layers, and geometric layers.

Aspect 4. The processor-implemented method of Aspect 3, wherein the temporal layers comprise one-dimensional convolutions along a trajectory-step dimension.

Aspect 5. The processor-implemented method of any one of Aspects 3 or 4, wherein the permutation layers allow features with different objects to interact.

Aspect 6. The processor-implemented method of any one of Aspects 3 to 5, wherein the geometric layers enable mixing between scalar and vector quantities that are combined in the internal representations.

Aspect 7. The processor-implemented method of any one of Aspects 1 to 6, wherein the geometric data types comprise scalars, vectors, and quaternions.

Aspect 8. The processor-implemented method of Aspect 7, further comprising transforming a quaternion into at least two rotation vectors.

Aspect 9. The processor-implemented method of Aspect 8, wherein transforming the quaternion into at least two rotation vectors comprises: mapping the quaternion to a corresponding element in a matrix representation; and selecting two column vectors of the matrix representation as the two rotation vectors.

Aspect 10. The processor-implemented method of any one of Aspects 8 or 9, wherein the scalars are associated with objects corresponding to the state-action pairs.

Aspect 11. The processor-implemented method of any one of Aspects 1 to 10, wherein transforming of the output data to the data representation is performed using linear maps.

Aspect 12. The processor-implemented method of Aspect 11, wherein transforming of the output data to the data representation using the linear maps comprises outputting one scalar for each input scalar, one vector for each input vector, and one scalar and one vector for each input quaternion.

Aspect 13. The processor-implemented method of any one of Aspects 1 to 12, further comprising: generating an equivariant diffusion model by combining an invariant base density and the equivariant denoising network.

Aspect 14. The processor-implemented method of Aspect 13, wherein the equivariant diffusion model is trained by adding noise to the state-action pairs to generate noisy trajectories, feeding the noisy trajectories into the equivariant denoising network, and outputting, using the equivariant diffusion model, one or more predicted original trajectories of the state-action pairs.

Aspect 15. The processor-implemented method of Aspect 14, further comprising sampling, using the equivariant diffusion model, trajectories unconditionally.

Aspect 16. The processor-implemented method of Aspect 14, further comprising sampling, using the equivariant diffusion model, trajectories conditionally based on initial goals and states.

Aspect 17. The processor-implemented method of any one of Aspects 14 to 16, further comprising sampling, using the equivariant diffusion model, trajectories with guidance from a classifier to solve a task.

Aspect 18. The processor-implemented method of Aspect 17, wherein sampling trajectories with guidance from the classifier to solve the task comprises using test time rewards and goal conditioning.

Aspect 19. The processor-implemented method of Aspect 17, wherein sampling trajectories with guidance from the classifier to solve the task comprises using rewards to specify a new task.

Aspect 20. The processor-implemented method of any one of Aspects 1 to 19, wherein the internal representations are associated with a symmetry group.

Aspect 21. The processor-implemented method of Aspect 20, wherein the symmetry group is a product of three distinct groups.

Aspect 22. The processor-implemented method of Aspect 21, wherein the three distinct groups comprise a symmetry of spatial translations and rotations group, a discrete time translation symmetry group, and a permutation group over n objects group.

Aspect 23. The processor-implemented method of Aspect 22, wherein the permutation group over n objects is associated with object properties that permute where robot properties or global properties of a state remain invariant.

Aspect 24. The processor-implemented method of any one of Aspects 22 or 23, wherein the symmetry of spatial translations and rotations group relates to representations comprising scalars, vectors, and quaternions.

Aspect 25. The processor-implemented method of Aspect 24, wherein the scalars remain invariant under a rotation associated with an angle between two objects, wherein the vectors are in a standard representation associated with a position or a velocity, and wherein the quaternions transform in a quaternionic representation associated with orientation.

Aspect 26. The processor-implemented method of Aspect 20, wherein the symmetry group is divided into at least one smaller symmetry group based on a condition.

Aspect 27. The processor-implemented method of Aspect 26, wherein the condition comprises at least one of a direction of gravity or an existence of distinguishable objects.

Aspect 28. The processor-implemented method of any one of Aspects 1 to 27, wherein spatial positions associated with the state-action pairs are expressed relative to a key object.

Aspect 29. The processor-implemented method of Aspect 28, wherein the key object comprises a position of a base of a robot or a center of mass of a robot.

Aspect 30. The processor-implemented method of any one of Aspects 1 to 29, wherein converting, via the training preparation engine, the geometric data types into the internal representations comprises at least one of transforming a regular representation under a time shift, transforming a regular representation under permutations, or transforming using scalar and vector representations.

Aspect 31. An apparatus for using diffusion models using symmetries in geometric structures, the apparatus comprising: at least one memory; and at least one processor coupled to at least one memory and configured to: receive, via a training preparation engine, a training dataset comprising state-action pairs; separate, via the training preparation engine, the state-action pairs from the training dataset into geometric data types; convert, via the training preparation engine, the geometric data types into internal representations; process, via an equivariant denoising network, the internal representations to generate output data; and transform the output data to a data representation.

Aspect 32. The apparatus of Aspect 31, wherein the equivariant denoising network includes alternating types of layers.

Aspect 33. The apparatus of Aspect 32, wherein the alternating types of layers comprise temporal layers, permutation layers, and geometric layers.

Aspect 34. The apparatus of Aspect 33, wherein the temporal layers comprise one-dimensional convolutions along a trajectory-step dimension.

Aspect 35. The apparatus of any one of Aspects 33 or 34, wherein the permutation layers allow features with different objects to interact.

Aspect 36. The apparatus of any one of Aspects 33 to 35, wherein the geometric layers enable mixing between scalar and vector quantities that are combined in the internal representations.

Aspect 37. The apparatus of any one of Aspects 31 to 36, wherein the geometric data types comprise scalars, vectors, and quaternions.

Aspect 38. The apparatus of Aspect 37, wherein the at least one processor is configured to transform a quaternion of the quaternions into at least two rotation vectors.

Aspect 39. The apparatus of Aspect 38, wherein, to transform the quaternion into at least two rotation vectors, the at least one processor is configured to: map the quaternion to a corresponding element in a matrix representation; and select two column vectors of the matrix representation as the two rotation vectors.

Aspect 40. The apparatus of any one of Aspects 37 or 28, wherein the scalars are associated with objects associated with the state-action pairs.

Aspect 41. The apparatus of any one of Aspects 31 to 40, wherein the at least one processor is configured to transform the output data to the data representation using linear maps.

Aspect 42. The apparatus of Aspect 41, wherein, based on transforming the output data to the data representation using the linear maps, the at least one processor is configured to output one scalar for each input scalar, one vector for each input vector, and one scalar and one vector for each input quaternion.

Aspect 43. The apparatus of any one of Aspects 31 to 42, wherein the at least one processor is configured to: generate an equivariant diffusion model by combining an invariant base density and the equivariant denoising network.

Aspect 44. The apparatus of Aspect 43, wherein the at least one processor is configured to train the equivariant diffusion model by adding noise to the state-action pairs to generate noisy trajectories, feeding the noisy trajectories into the equivariant denoising network, and outputting, using the equivariant diffusion model, one or more predicted original trajectories of the state-action pairs.

Aspect 45. The apparatus of Aspect 44, wherein the at least one processor is configured to sample trajectories unconditionally using the equivariant diffusion model.

Aspect 46. The apparatus of Aspect 44, wherein the at least one processor is configured to sample trajectories conditionally based on initial goals and states using the equivariant diffusion model.

Aspect 47. The apparatus of any one of Aspects 44 to 46, wherein the at least one processor is configured to sample trajectories with guidance from a classifier to solve a task using the equivariant diffusion model.

Aspect 48. The apparatus of Aspect 47, wherein, to sample trajectories with guidance from the classifier to solve the task, the at least one processor is configured to use test time rewards and goal conditioning.

Aspect 49. The apparatus of Aspect 47, wherein, to sample trajectories with guidance from the classifier to solve the task, the at least one processor is configured to use rewards to specify a new task.

Aspect 50. The apparatus of any one of Aspects 31 to 49, wherein the internal representations are associated with a symmetry group.

Aspect 51. The apparatus of Aspect 50, wherein the symmetry group is a product of three distinct groups.

Aspect 52. The apparatus of Aspect 51, wherein the three distinct groups comprise a symmetry of spatial translations and rotations group, a discrete time translation symmetry group, and a permutation group over n objects group.

Aspect 53. The apparatus of Aspect 52, wherein the permutation group over n objects is associated with object properties that permute where robot properties or global properties of a state remain invariant.

Aspect 54. The apparatus of any one of Aspects 52 or 53, wherein the symmetry of spatial translations and rotations group relates to representations comprising scalars, vectors, and quaternions.

Aspect 55. The apparatus of Aspect 54, wherein the scalars remain invariant under a rotation associated with an angle between two objects, wherein the vectors are in a standard representation associated with a position or a velocity, and wherein the quaternions transform in a quaternionic representation associated with orientation.

Aspect 56. The apparatus of Aspect 50, wherein the symmetry group is divided into at least one smaller symmetry group based on a condition.

Aspect 57. The apparatus of Aspect 56, wherein the condition comprises at least one of a direction of gravity or an existence of distinguishable objects.

Aspect 58. The apparatus of any one of Aspects 31 to 57, wherein spatial positions associated with the state-action pairs are expressed relative to a key object.

Aspect 59. The apparatus of Aspect 58, wherein the key object comprises a position of a base of a robot or a center of mass of a robot.

Aspect 60. The apparatus of any one of Aspects 31 to 59, wherein, to convert the geometric data types into the internal representations, the at least one processor is configured to at least one of transform a regular representation under a time shift, transform a regular representation under permutations, or transform using scalar and vector representations.

Aspect 61. A non-transitory computer-readable medium having stored thereon instructions that, when executed by one or more processors, cause the one or more processors to perform operations according to any of Aspects 1 to 30.

Aspect 62. An apparatus for processing data during an equivariant diffuser, the apparatus including one or more means for performing operations according to any of Aspects 1 to 30.

Aspect 61. A non-transitory computer-readable medium having stored thereon instructions that, when executed by one or more processors, cause the one or more processors to perform operations according to any of Aspects 1 to 30.

Aspect 62. An apparatus for processing data during an equivariant diffuser, the apparatus including one or more means for performing operations according to any of Aspects 1 to 30.

What is claimed is:

1. A processor-implemented method of modeling tasks using a geometric structure, the processor-implemented method comprising:
receiving, via a training preparation engine, a training dataset comprising state-action pairs;
separating, via the training preparation engine, the state-action pairs from the training dataset into geometric data types;
converting, via the training preparation engine, the geometric data types into internal representations;
processing, via an equivariant denoising network, the internal representations to generate output data; and
transforming the output data to a data representation.

2. The processor-implemented method of claim 1, wherein the equivariant denoising network includes alternating types of layers.

3. The processor-implemented method of claim 2, wherein the alternating types of layers comprise temporal layers, permutation layers, and geometric layers.

4. The processor-implemented method of claim 3, wherein the temporal layers comprise one-dimensional convolutions along a trajectory-step dimension, wherein the permutation layers allow features with different objects to interact, and wherein the geometric layers enable mixing between scalar and vector quantities that are combined in the internal representations.

5. The processor-implemented method of claim 1, wherein the geometric data types comprise quaternions and wherein the processor-implemented method further comprises transforming a quaternion into at least two rotation vectors.

6. The processor-implemented method of claim 5, wherein transforming the quaternion into at least two rotation vectors comprises:
mapping the quaternion to a corresponding element in a matrix representation; and
selecting two column vectors of the matrix representation as the at least two rotation vectors.

7. The processor-implemented method of claim 1, wherein transforming of the output data to the data representation is performed using linear maps.

8. The processor-implemented method of claim 7, wherein transforming of the output data to the data representation using the linear maps comprises outputting one scalar for each input scalar, one vector for each input vector, and one scalar and one vector for each input quaternion.

9. The processor-implemented method of claim 1, further comprising:
generating an equivariant diffusion model by combining an invariant base density and the equivariant denoising network.

10. The processor-implemented method of claim 9, wherein the equivariant diffusion model is trained by adding noise to the state-action pairs to generate noisy trajectories, feeding the noisy trajectories into the equivariant denoising network, and outputting, using the equivariant diffusion model, one or more predicted original trajectories of the state-action pairs.

11. The processor-implemented method of claim 10, further comprising sampling, using the equivariant diffusion model, trajectories unconditionally.

12. The processor-implemented method of claim 10, further comprising sampling, using the equivariant diffusion model, trajectories conditionally based on initial goals and states.

13. The processor-implemented method of claim 10, further comprising sampling, using the equivariant diffusion model, trajectories with guidance from a classifier to solve a task.

14. The processor-implemented method of claim 13, wherein sampling trajectories with guidance from the classifier to solve the task comprises using test time rewards and goal conditioning.

15. The processor-implemented method of claim 13, wherein sampling trajectories with guidance from the classifier to solve the task comprises using rewards to specify a new task.

16. The processor-implemented method of claim 1, wherein the internal representations are associated with a symmetry group.

17. The processor-implemented method of claim 16, wherein the symmetry group is a product of three distinct groups.

18. The processor-implemented method of claim 17, wherein the three distinct groups comprise a symmetry of spatial translations and rotations group, a discrete time translation symmetry group, and a permutation group over n objects group.

19. The processor-implemented method of claim 18, wherein the permutation group over n objects is associated with object properties that permute where robot properties or global properties of a state remain invariant.

20. The processor-implemented method of claim 18, wherein the symmetry of spatial translations and rotations group relates to representations comprising scalars, vectors, and quaternions.

21. The processor-implemented method of claim 20, wherein the scalars remain invariant under a rotation associated with an angle between two objects, wherein the vectors are in a standard representation associated with a position or a velocity, and wherein the quaternions transform in a quaternionic representation associated with orientation.

22. The processor-implemented method of claim 16, wherein the symmetry group is divided into at least one smaller symmetry group based on a condition.

23. The processor-implemented method of claim 22, wherein the condition comprises at least one of a direction of gravity or an existence of distinguishable objects.

24. The processor-implemented method of claim 1, wherein spatial positions associated with the state-action pairs are expressed relative to a key object.

25. The processor-implemented method of claim 24, wherein the key object comprises a position of a base of a robot or a center of mass of a robot.

26. The processor-implemented method of claim 1, wherein converting, via the training preparation engine, the geometric data types into the internal representations comprises at least one of transforming a regular representation under a time shift, transforming a regular representation under permutations, or transforming using scalar and vector representations.

27. An apparatus for using diffusion models using symmetries in geometric structures, the apparatus comprising:
at least one memory; and
at least one processor coupled to at least one memory and configured to:
receive, via a training preparation engine, a training dataset comprising state-action pairs;
separate, via the training preparation engine, the state-action pairs from the training dataset into geometric data types;
convert, via the training preparation engine, the geometric data types into internal representations;
process, via an equivariant denoising network, the internal representations to generate output data; and
transform the output data to a data representation.

28. The apparatus of claim 27, wherein the at least one processor is configured to:
generate an equivariant diffusion model by combining an invariant base density and the equivariant denoising network.

29. A non-transitory computer-readable medium having stored thereon instructions that, when executed by one or more processors, cause the one or more processors to be configured to:
receive, via a training preparation engine, a training dataset comprising state-action pairs;
separate, via the training preparation engine, the state-action pairs from the training dataset into geometric data types;
convert, via the training preparation engine, the geometric data types into internal representations;
process, via an equivariant denoising network, the internal representations to generate output data; and
transform the output data to a data representation.

30. An apparatus for processing data during an equivariant diffuser, the apparatus including one or more:
means for receiving, via a training preparation engine, a training dataset comprising state-action pairs;
means for separating, via the training preparation engine, the state-action pairs from the training dataset into geometric data types;
means for converting, via the training preparation engine, the geometric data types into internal representations;
means for processing, via an equivariant denoising network, the internal representations to generate output data; and
means for transforming the output data to a data representation.
